(19) United States
(12) Patent Application Publication
(10) Pub. No.: US 2016/0329206 A1
(43) Pub. Date: Nov. 10, 2016

(54) METHODS OF MODULATING RESIDUAL STRESS IN THIN FILMS

(71) Applicant: Lam Research Corporation, Fremont, CA (US)

(72) Inventors: Purushottam Kumar, Hillsboro, OR (US); Hu Kang, Tualatin, OR (US); Jun Qian, Sherwood, OR (US); Adrien LaVoie, Newberg, OR (US)

(21) Appl. No.: 14/708,050

(22) Filed: May 8, 2015

(51) Int. Cl. H01L 21/02

(52) U.S. Cl. CPC H01L 21/022; H01L 21/02164; H01L 21/02167; H01L 21/0217; H01L 21/02266; H01L 21/02271

(57) ABSTRACT

Disclosed are methods of forming reduced-stress dielectric films on semiconductor substrates which include depositing a first reduced-stress bilayer by depositing a main portion of thickness tₘ and stress level sₘ, and depositing a low stress portion of thickness tₗ and stress level sₗ, where sₗ<sₘ. The first reduced-stress bilayer may be characterized by an overall stress level sₜₒₜ<90%*(sₘ*tₘ+sₗ*tₗ)/(tₘ+tₗ), and in some cases, sₜₒₜ<sₗ. In some cases, sₜₒₜ<90%*sₘ and the main and low stress portions may have substantially the same chemical composition within a margin of 5.0 mole percent per unit volume for each individual elemental component. In some embodiments, the main and low stress portions may be characterized by leakage currents Iₘ and Iₗ, respectively, breakdown voltages Vₘ and Vₗ, respectively, and the first reduced-stress bilayer may be characterized by an overall leakage current Iₜₒₜ and overall breakdown voltage Vₜₒₜ such that sₜₒₜ<90%*sₘ, and Iₜₒₜ<90%*(Iₘ*tₘ+Iₗ*tₗ)/(tₘ+tₗ) or Vₜₒₜ>110%*(Vₘ*tₘ+Vₗ*tₗ)/(tₘ+tₗ) or both.

### BACKGROUND

Most film deposition is associated with the introduction of residual stress in the deposited film due to both extrinsic factors (e.g., thermal expansion coefficient mismatch) and/or intrinsic factors (e.g., defects and/or dislocations with lattice). The stress can be either compressive or tensile depending, for instance, on the characteristics of the substrate, the type of film being deposited, its properties, the manner of its deposition, etc. Compressive stress in the deposited films can lead to blistering or buckling of the film whereas tensile stress may lead to film cracking. Additionally, the wafer distortion induced by these stresses can cause reliability issue in other device layers and, generally, adversely impact electrical and optical performance, as well as the mechanical integrity of the fabricated semiconductor device. Thus, in IC fabrication, film stress is a major concern of the device layer integration strategy.

### SUMMARY

Disclosed herein are methods of forming reduced-stress dielectric films on semiconductor substrates. The methods include depositing a first reduced-stress bilayer of the dielectric film by depositing a main portion having a thickness tₘ and stress level sₘ, and depositing a low stress portion having a thickness tₗ and stress level sₗ where sₗ<sₘ. In some embodiments, the first reduced-stress bilayer deposited according to the foregoing may be characterized by an overall stress level sₜₒₜ<90%*(sₘ*tₘ+sₗ*tₗ)/(tₘ+tₗ). In certain such embodiments, the first reduced stress bilayer may be characterized by an overall stress level sₜₒₜ<sₗ. In some embodiments, the first reduced-stress bilayer may be characterized by an overall stress level sₜₒₜ<90%*sₘ, and the main and low stress portions of the first reduced-stress bilayer may have substantially the same chemical composition within a margin of 5.0 mole percent per unit volume for each individual elemental component.

In some embodiments, the deposited reduced-stress dielectric film may be made up of oxides, nitrides, and/or carbides of silicon. In some embodiments, depositing the main and low-stress portions of the first reduced-stress bilayer may include: adsorbing a film precursor onto the substrate in a processing chamber such that the film precursor forms an adsorption-limited layer of film precursor on the substrate; removing at least some unadsorbed film precursor from a volume within the processing chamber surrounding the adsorbed film precursor; and after removing unadsorbed film precursor, reacting the adsorbed film precursor by exposing it to a plasma to form a dielectric film layer on the substrate.

In some embodiments, depositing the first reduced-stress bilayer of dielectric film may include depositing a main portion having a thickness tₘ, stress level sₘ, leakage current Iₘ, and breakdown voltage Vₘ, depositing a low stress portion having a thickness tₗ, stress level sₗ where sₗ<sₘ, leakage current Iₗ, and breakdown voltage Vₗ. In certain such embodiments, the first reduced-stress bilayer may be characterized by an overall stress level sₜₒₜ, overall leakage current Iₜₒₜ, and overall breakdown voltage Vₜₒₜ such that sₜₒₜ<90%*sₘ, and Iₜₒₜ<90%*(Iₘ*tₘ+Iₗ*tₗ)/(tₘ+tₗ) or Vₜₒₜ>110%*(Vₘ*tₘ+Vₗ*tₗ)/(tₘ+tₗ) or both.

Also disclosed herein are methods of forming a reduced-stress dielectric film on a semiconductor substrate which include depositing a first reduced-stress bilayer of dielectric film by depositing a main portion, wherein the total RF energy applied to the main portion while it is being deposited, per unit film area and thickness, is more than about 0.16 Joules/cm², and depositing a low stress portion, wherein the total RF energy applied to the low stress portion while it is being deposited, per unit film area and thickness, is less than about 0.1 Joules/cm². In certain such embodiments, the RF power level applied in the deposition of the main portion is more than about 0.7 Watts/cm², and the RF power level applied in the deposition of the low stress portion is less than about 0.4 Watts/cm². In some embodiments, RF power is applied in the deposition of the main portion for more than about 0.1 seconds/cycle, and RF power is applied in the deposition of the low-stress portion for less than about 0.5 seconds/cycle.

### BRIEF DESCRIPTION OF THE DRAWINGS

FIG. 1A plots compressive stress, deposition rate, and non-uniformity versus plasma RF power for single layer films.

FIG. 1B plots breakdown voltage versus plasma RF power for single layer films.

FIG. 1C plots leakage current versus plasma RF power for single layer films.

FIGS. 1D and 1E plot capacitance versus voltage in the forward and reverse scan directions for single layer films deposited using 500 W and 2500 W RF plasma power, respectively.

FIG. 1F plots capacitance versus voltage in the forward scan direction for single layer films deposited using a range of RF plasma power levels.

FIG. 1G plots current versus voltage for single layer films deposited using a range of RF plasma power levels, illustrating leakage current levels and breakdown voltages.

FIG. 2A schematically illustrates a multi-layer film stack having 4 pairs of reduced-stress bilayers.

FIG. 2B plots compressive stress versus thickness ratio (the ratio of low stress interlayer thickness to total film thickness) for the 4-bilayer film schematically illustrated in FIG. 2A.

FIGS. 2C and 2D plot, respectively, breakdown voltage and leakage current versus thickness ratio for the 4-bilayer film of FIG. 2A.

FIGS. 2E(i) through 2E(v) plot capacitance versus voltage in the forward and reverse scan directions for the 4-bilayer film of FIG. 2A over a range of increasing thickness ratios.

FIGS. 2F and 2G plot current versus voltage and capacitance versus voltage, respectively, for the 4-bilayer film of FIG. 2A deposited over a range of thickness ratios.

FIG. 3A schematically illustrates a high-stress film having a main film portion but no low-stress interlayer film portions.

FIGS. 3B and 3C schematically illustrate two different 4-bilayer film configurations wherein each bilayer includes a main portion and a low-stress interlayer portion.

FIGS. 3D and 3E schematically illustrate two different film configurations having 2 bilayers (each including a main portion and a low-stress interlayer portion) and additionally another single layer of high-stress film.

FIG. 3F schematically illustrates a single bilayer film wherein the low-stress interlayer portion is deposited first (below) the main portion of the bilayer.

FIG. 4A plots current versus voltage for the 2-bilayer configurations schematically illustrated in FIGS. 3B and 3C, deposited using 2 different combinations of plasma power levels.

FIG. 4B plots capacitance versus voltage in the forward scan direction for the 2-bilayer configurations schematically illustrated in FIGS. 3B and 3C, deposited using 2 different combinations of plasma power levels.

FIG. 4C plots current versus voltage for the 4-bilayer configuration of FIG. 3B in comparison with the 1-bilayer configuration of FIG. 3F, each configuration deposited at 2 thickness ratios.

FIG. 4D plots capacitance versus voltage in the forward scan direction for the 4-bilayer configuration of FIG. 3B in comparison with the 1-bilayer configuration of FIG. 3F, each configuration deposited at 2 thickness ratios.

FIGS. 4E and 4F plot capacitance versus voltage in the forward and reverse scan directions for film having the 1-bilayer configuration of FIG. 4F deposited at thickness ratios of 11% and 33%, respectively.

FIG. 5A plots residual film stress versus the plasma RF power used to deposit the low-stress interlayer.

FIGS. 5B and 5C plot breakdown voltage and leakage current, respectively, versus the plasma RF power used to deposit the low-stress interlayer.

FIG. 5D plots current versus voltage for different films formed using various plasma RF power levels for depositing the low-stress interlayer.

FIG. 5E plots capacitance versus voltage, in the forward scan direction, for different films formed using various plasma RF power levels for depositing the low-stress interlayer.

FIG. 6 presents a flowchart of a cyclic ALD process for depositing a dielectric film.

FIG. 7 presents a substrate processing apparatus including a reaction chamber for depositing reduced-stress dielectric films according to various techniques and operations disclosed herein.

FIG. 8 presents a multi-station substrate processing apparatus including a controller for depositing reduced-stress dielectric films on multiple substrates in accordance with various techniques and operations disclosed herein.

### DETAILED DESCRIPTION

In the following description, numerous specific details are set forth in order to provide a thorough understanding of the present invention. However, the present invention may be practiced without some or all of these specific details. In other instances, well known process operations or hardware have not been described in detail so as to not unnecessarily obscure the inventive aspects of the present work. While the invention will be described in conjunction with specific detailed embodiments, it is to be understood that these specific detailed embodiments are not intended to limit the scope of the inventive concepts disclosed herein.

### INTRODUCTION

In processes of depositing dielectric films on semiconductor substrates it has been observed that, in many instances, variations in process conditions which lead to an improvement in deposited film quality are accompanied by unwanted increases is residual film stress (either compressive or tensile). An example of this tradeoff arises in film forming techniques based on atomic layer deposition (ALD) processes.

ALD has become a popular technique for achieving the high-quality deposition of conformal films—i.e., films of material having a substantially uniform thickness relative to the shape of the underlying structure, even if non-planar; conformal films are thus of great importance and value as the IC industry moves more and more to architectures employing 3D device structures (e.g., Intel's Tri-Gate transistor). What makes ALD well-suited to the deposition of conformal films is, inter alia, the fact that a single cycle of ALD only deposits a single thin layer of material, the thickness being limited by the amount of one or more film precursor reactants which may adsorb onto the substrate surface (i.e., forming an adsorption-limited layer) prior to the film-forming chemical reaction itself. Multiple “ALD cycles” may then be used to build up a film of the desired thickness, and since each layer (sometimes just a molecular monolayer) is thin and conformal, the resulting film substantially conforms to the shape of the underlying device structure.

As described in further detail below, deposition of films via ALD may employ a powered showerhead and grounded pedestal in a reaction chamber, between which plasma-enhanced conversion of ALD precursors happens on wafer surface. Cyclic ALD process generally include a step of precursor dosing to form an adsorption-limited layer of film precursor, followed by a post-dose purge to remove unabsorbed precursor, followed by plasma conversion of the adsorbed precursor, and in some embodiments a post-RF purge of unreacted and/or desorbed precursor. The reactant gases, purge gases, etc. may be delivered to the reaction chamber through the aforementioned showerhead as described below. In dielectric film formation, the plasma activation step may involve igniting a plasma in the reaction chamber in the presence of oxidizing reactant gas mixture such as N₂O, O₂, Ar which activates the surface reaction of adsorbed precursor to covert it into a dielectric film: oxides, nitrides, and/or carbides of silicon, for example. Such a cyclic ALD process may be repeated until the desired thickness of film is obtained.

However, as stated, ALD represents a class of film deposition techniques which exhibits the aforementioned tradeoff between film quality and residual film stress (though it is noted that the tradeoff is also seen with films deposited via physical vapor deposition (PVD) and chemical vapor deposition (CVD), and in particular plasma enhanced CVD (PECVD)). For a dielectric film of SiOₓ deposited via ALD on a silicon substrate, the typical residual stress is compressive. In this case, one sees that higher residual compressive stress results from the process conditions—such as increased deposition temperature, increased RF power and/or RF time (more generally, increased RF energy applied to the film while it is deposited)—which generally also lead to improvements in deposited film quality—e.g., wet etch rate (WER), dry etch rate (DER), electrical properties such as leakage current, breakdown voltage, etc.

Thus, although one ideally wants good film properties at minimal stress, in practice, improved film properties are accompanied with undesirably high stress levels, compressive or tensile. Note that the word “stress” when used herein refers to the magnitude of the film stress level (irrespective of its sign/directionality), with the words “compressive” and “tensile” (as those terms are understood by those skilled in the art) being used to identify the sign/directionality of the “stress,” where appropriate.

Single Layer-Type Films: Low Stress Versus High Stress

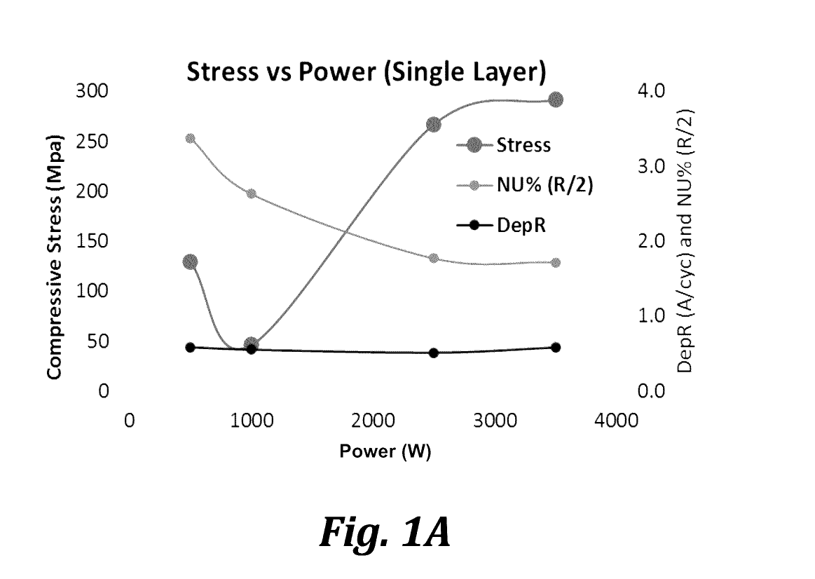

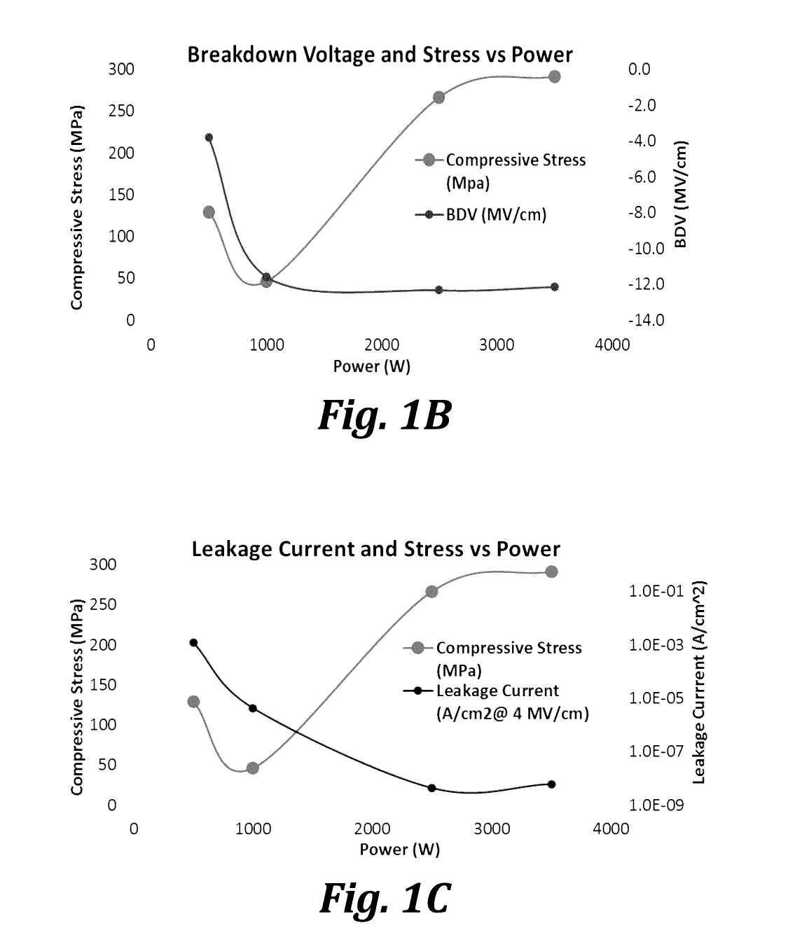

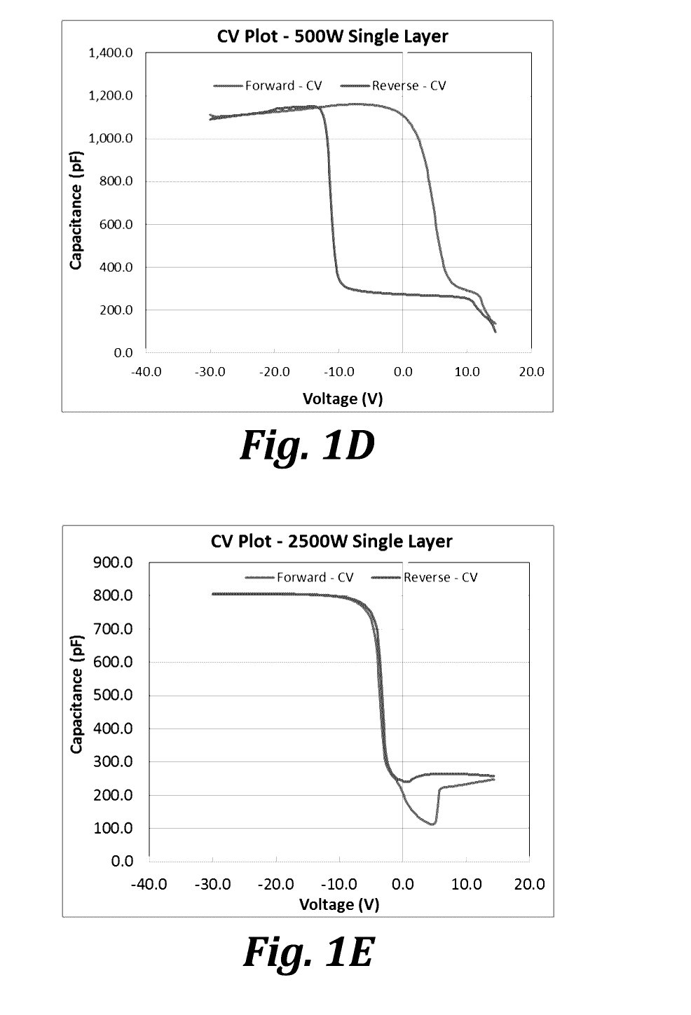

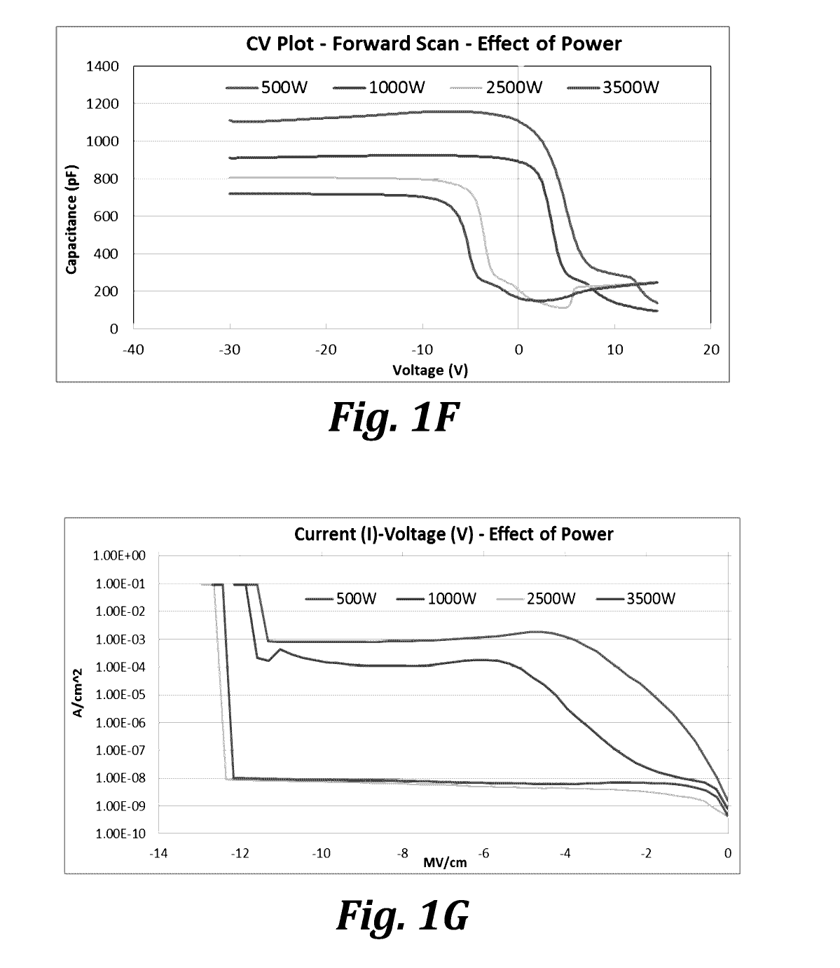

An example illustrating the tradeoff between improved film properties and a contemporaneous increase in residual stress is shown in FIGS. 1A-1F. The experiments were performed at 4 plasma RF power levels as shown in Table I, with the same data also plotted graphically in FIG. 1A. Note that these experiments (FIGS. 1A-1F) were carried out in a 4-station processing apparatus (as schematically illustrated in FIG. 8 and described below) and, accordingly, the RF power level per wafer substrate (in this case 300 mm diameter wafers) is calculated by dividing by 4 the RF power levels recited in Table I (and noted in the figures).

TABLE I

| Power (W) | Mean | NU % | Compressive Stress |
|---|---|---|---|
| (4 stations) | (A) | (R/2) | (Mpa) |
| 500 | 1170.8 | 3.38 | 129.6 |
| 1000 | 1105.7 | 2.63 | 46.1 |
| 2500 | 1025.5 | 1.77 | 266.8 |
| 3500 | 1164.3 | 1.72 | 291.7 |

The data corresponds to the deposition of SiO₂ film via an ALD process performed at 400 C where each cycle of the ALD process employed substantially the same process conditions. In other words, the layer of film deposited in each ALD cycle is substantially identical in composition and properties; thus the end product of the entire sequence of ALD cycles may be thought of as multiple layers of but a single film type, or collectively as a single monolithic layer of film (since the individual layers are substantially indistinguishable).

FIGS. 1B and 1C illustrate that important film properties—breakdown voltage in FIG. 1B and leakage current in FIG. 1C—improve when the films are deposited at the higher plasma power levels shown in Table I, but again, at the cost of the films having significantly increased residual film stress levels. Likewise, FIGS. 1D and 1E are capacitance-voltage (CV) plots of films deposited using 500 and 2500 W plasma power, respectively, and once again it is seen that the higher plasma-power deposition (with higher stress) leads to improved properties—in this case, that the film deposited at 2500 W shows greatly reduced CV hysteresis versus the film deposited at 500 W; and, an illustration that capacitance generally improves as deposition plasma power is increased is shown by the data in FIG. 1F. Finally, FIG. 1G illustrates that leakage current is reduced (flat portions of current vs. voltage plotlines), and that breakdown voltages have larger magnitudes (sharp vertical portions of the plotlines toward the left of the figure at large voltage magnitudes) for the films deposited at 2500 and 3500 W plasma power levels (associated with the higher compressive stress levels).

In sum, due to this apparent tradeoff between good film properties and high film stress (either compressive or tensile), what has been sought is a method of depositing reduced stress films which nevertheless possess the desirable properties generally associated with high stress films.

Multi-Layering of High/Low Stress Films to Reduce Overall Film Stress Level

Disclosed herein are methods of forming reduced-stress films on semiconductor substrates which, although having lower residual stress levels, nevertheless possess (at least to a certain extent) the desirable film properties generally characteristic of films having high residual stress levels. Depending on the embodiment, examples of such films may include dielectric films of SiOx, SiNx, SiOxNy, SiCxNy, SiCx, TiOx (for different values and combinations of x and y), or other dielectrics, and such film properties may include, but are not limited to, wet etch rate (WER) and dry etch rate (DER), and electrical properties such as leakage current and breakdown voltage. In some embodiments, these methods of forming reduced-stress films may be used for deposition of low-stress ALD films for PMD STI fill in logic chip and DRAM manufacturing and for slit 1 and slit 2 fills in NAND and 3DNAND applications.

In general, the way this is accomplished is through the introduction of one or more low stress interlayers into what would otherwise be a high stress film, thus forming one or more low stress film portions within the deposited film stack. By engineering films in this manner, it has been observed that the overall residual stress level of the film may be significantly reduced—relative to what the film's residual stress level would otherwise be without the introduction of the interlayers—even (in some cases) if the portion(s) of the film formed by the interlayers represent a relatively minor proportion of the entire deposited film stack. Moreover, it has been observed that while the interlayers reduce the film's residual stress level considerably, various other properties of what would otherwise be a high stress film are not substantially affected by the presence of the interlayers.

Thus, through the introduction of low stress interlayers, it is seen that one may engineer a low stress film having the desirable properties of a high-stress film. In the specific context of a cyclic deposition process such as ALD (as described above)—but also in the context of other deposition processes such as CVD, PECVD, PVD, etc. which may also be used in cyclic fashion for film deposition (or generally apply to any cyclic film deposition process)—this may be achieved through the alteration of process conditions at one or more intervals during the repeating cycles of layer-by-layer deposition. In some embodiments, these “low stress interlayers” may have substantially the same chemical composition as the other layers, but nevertheless have a different residual stress level due to a change in process conditions such as plasma power, for example.

To precisely understand the significance and scope of what is disclosed herein, it is important first to understand precisely what is meant herein by the phrase: “low-stress interlayer.” In the context of a cyclic deposition process such as ALD, each deposition cycle deposits a thin layer of material of substantially the same composition and properties. Thus, while each cycle deposits a “layer” of material, the boundaries between these layers may not be discernable—because the layers are the substantially the same (in composition and properties)—and as a result the whole deposited film stack may appear as a single monolithic “layer.” Accordingly, what is meant by “layer” depends on context: it may refer to what is deposited in a single deposition cycle; or, it may refer to a monolithic layer of uniform composition which results from the sequential cyclic deposition of many layers having the same composition. As far as the phrase “low stress interlayer,” it could likewise be left to depend on context, but instead, for sake of concreteness, it is hereby stated to refer to a portion of a deposited film which is formed via one or more consecutive deposition cycles performed under process conditions which cause it to have a low residual stress level relative to the main (high-stress) portions of the film stack. This would typically be several cycles of deposition in an ALD process, but it may typically be a single cycle of deposition in a CVD, PECVD, or PVD process where a single cycle may deposit a more appreciable thickness of film material. For these reasons, it is often simpler to refer to the total reduced-stress film as having one or more main portions (which would by themselves have high residual stress), and one or more low-stress portions which reduce the overall stress level of the total film.

The concept of a reduced-stress bilayer then refers to the pairing of a low-stress film portion with a main film portion (which would by itself have higher stress). With respect to such a bilayer, one may refer to the thickness-weighted average (“TWA”) of various film properties associated with it. For example, for a film bilayer having a main portion of thickness tₘ, and stress level sₘ, and a low stress portion having a thickness tₗ and stress level sₗ, (note, sₗ<sₘ), the thickness-weighted average (“TWA”) of the stress levels is given by the relation

s_{TWA}=(sₘ*tₘ+sₗ*tₗ)/(tₘ+tₗ).

Likewise, the thickness-weighted average of any film property, say p, is given by

p_{TWA}=(pₘ*tₘ+pₗ*tₗ)/(tₘ+tₗ),

where pₘ and pₗ refer to the values of property p for the main and low-stress layers individually, respectively. For example, for a bilayer having two layers of equal thickness, the TWA of some property over the two layers is exactly equal to the average value of the property for the two layers; and for a bilayer having one layer thicker than the other, the property of the thicker layer will receive more weight when computing the TWA. More generally, one may refer to the TWA of a multi-layer structure of say N layers,

$${p}_{TWA} = {\sum }_{i = 1}^{N} {p}_{i} * {t}_{i} / {\sum }_{i = 1}^{N} {t}_{i}$$

where pᵢ and tᵢ correspond to the property associated with, and the thickness of, the ith layer and, again, with the term “layer” referring to the monolithic layer of substantially uniform composition which may result from several sequential deposition cycles performed under the same process conditions.

This is not to say that the value of a property actual measured with respect to a bilayer or other multi-layered structure, call it pₜₒₜ, is necessarily equal to the thickness-weighted average (TWA) of the same property as measured with respect to the individual film portions making up the multi-layered structure. One generally would expect this to be the case; what is surprising is that for certain properties corresponding to certain bilayer configurations, the TWA rule-of-thumb has actually been found not to be the case.

Take residual film stress, for example: it has been found that the introduction of a low-stress interlayer (into what would otherwise be a film having a high residual stress level) reduces residual stress levels sₜₒₜ (as measured) significantly more than what would be predicted by the thickness weighted average (TWA) stress level of the individual components of the film stack. In some embodiments, the reduction in sₜₒₜ may be to less than 95% of the stress level predicted by the TWA, or in some embodiments to less than 90% of the TWA, or to less than 85% of the TWA, or even to less than 75% of the TWA. This may be true, for instance, even if the main and low stress portions of the bilayer have substantially the same chemical composition, say within a margin of 10 mole percent (%) per unit volume for each individual elemental component, or in some embodiments to within a margin of 5 mole percent (%) per unit volume for each individual elemental component, or even to within 2% or 1%, depending on the embodiment. What is more surprising though is that in some examples (see below), the measured residual stress level sₜₒₜ has been found to even be less than the residual stress level sₗ of the low-stress interlayer (were it deposited by itself), (i.e., that sₜₒₜ<sₗ). Presumably this occurs through a synergistic redistributing of stress within the low stress/high stress film stack.

Thus, for instance, if for a single bilayer the quantities sₜₒₜ, sₘ, and sₗ refer to the residual stress of the bilayer, the residual stress of just the bilayer's main portion (i.e., without the interlayer), and the residual stress of just the interlayer (i.e., without the main portion), respectively, then said reduced-stress bilayer may be such that sₘ is greater than about 200, 225, 250, 275, or 300 MPa compressive; and sₗ may be less than 225, 200, 175, 150, or 125 MPa compressive—but for a given combination less than sₘ; and thereby sₜₒₜ may be less than 225, 200, 175, 150, or 125 MPa compressive—again, for a given combination less than sₘ, and in some cases even less than sₗ (as described in the preceding paragraph). Likewise, for a tensile film, these same quantities may be such that sₘ is greater than about 200, 225, 250, 275, or 300 MPa tensile; and sₗ may be less than 225, 200, 175, 150, or 125 MPa tensile—but for a given combination less than sₘ; and thereby sₜₒₜ may be less than 225, 200, 175, 150, or 125 MPa tensile—again, for a given combination less than sₘ, and in some cases even less than sₗ (again, as described in the preceding paragraph).

The thickness-weighted average (TWA) concept may also be used to understand and quantify the extent to which the desirable film properties of a high-stress film are maintained—in some cases, to a greater extent than one might expect—despite the fact that a low-stress interlayer is used to reduce the total overall residual film stress. For instance, two desirable properties of high-stress films are low leakage current and high breakdown voltage and it has been found that by combining a low stress interlayer portion with a high-stress main film portion, one may significantly reduce the overall residual stress level of the total film while largely maintaining its leakage current and breakdown voltage to an extent much better than what would be predicted by the TWA of these properties over the combined film. Thus, in some embodiments, it is seen that for a film having a bilayer with a main (high-stress) portion and a low stress interlayer portion, the total residual stress of the bilayer may be reduced to sₜₒₜ<90%*sₘ, or even to sₜₒₜ<80%*sₘ, where sₘ is the stress level of the main portion individually, while the overall leakage current may be maintained at Iₜₒₜ<90%*I_{TWA}, or the breakdown voltage maintained at Vₜₒₜ>110%*V_{TWA}, or both may be maintained as such, where (following the definitions above)

I_{TWA}=(Iₘ*tₘ+Iₗ*tₗ)/(tₘ+tₗ),

V_{TWA}=(Vₘ*tₘ+Vₗ*tₗ)/(tₘ+tₗ),

tₘ and tₗ being the thicknesses of the main and low stress film portions, respectively, Iₘ and Iₗ being the leakage currents of the main and low stress film portions, respectively, and Vₘ and Vₗ being the breakdown voltages of the main and low stress film portions, respectively. In some embodiments, the bilayer of the film may be such that Iₜₒₜ<80%*I_{TWA}, or the breakdown voltage maintained at Vₜₒₜ>120%*V_{TWA}, or both. The experiments described below involve films exhibiting one or more of these properties.

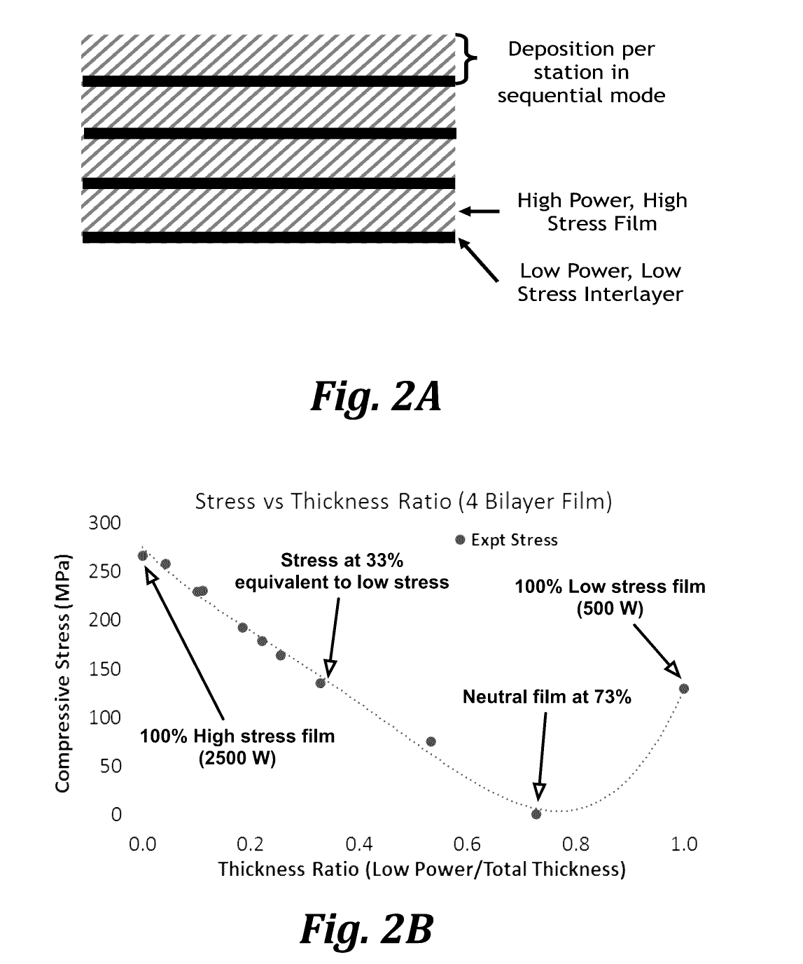

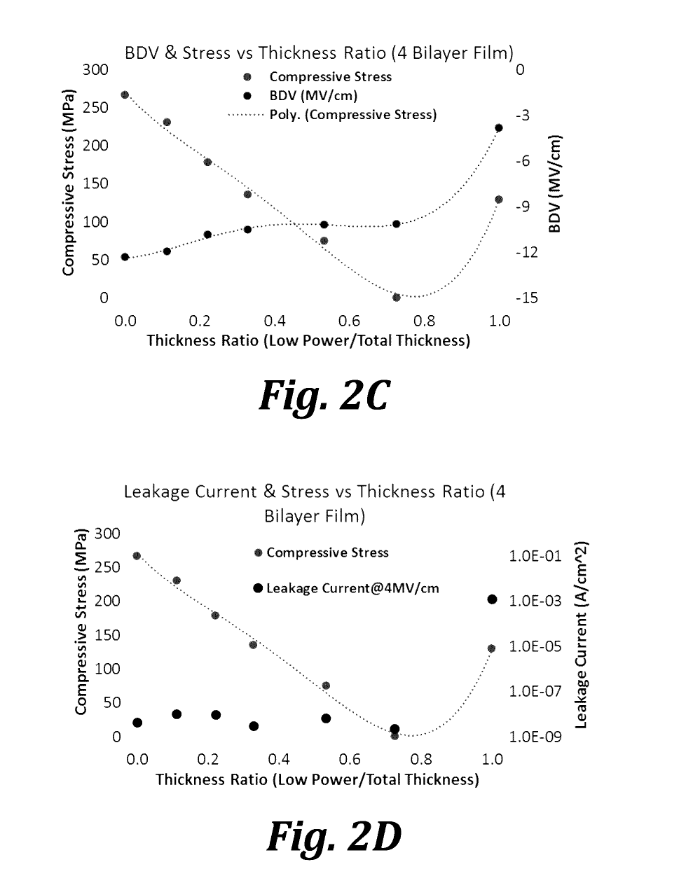

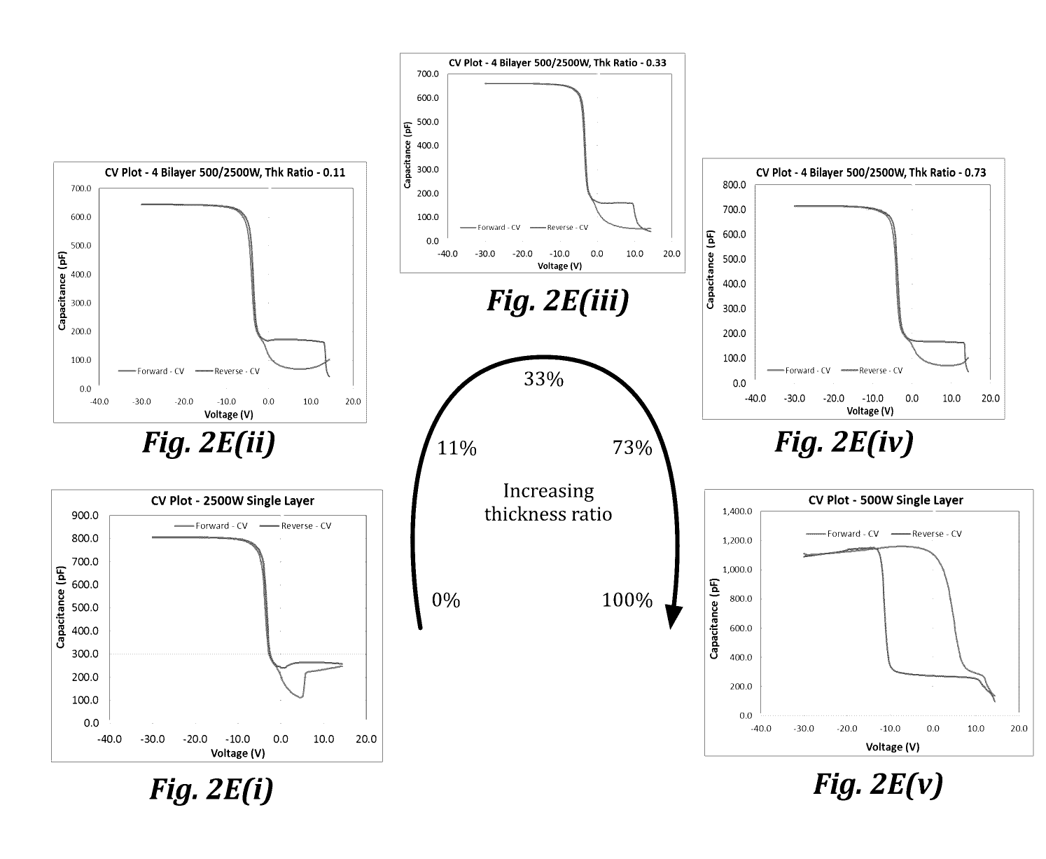

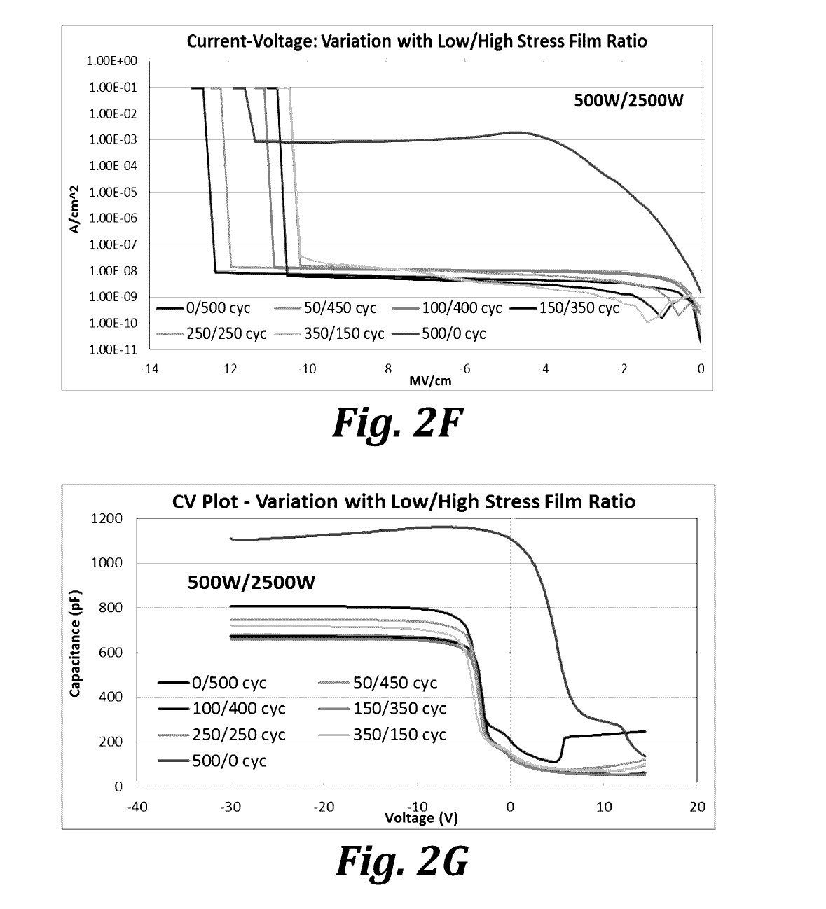

The interlayer insertion methods for reducing film stress are described above with respect to a single bilayer of film (having a main portion and a low-stress interlayer portion); however, one of ordinary skill in the art will appreciate that a film stack having multiple interlayers may be constructed from 2, or 3, or 4, or 5, or more bilayers as just described. A schematic of such a film having 4 bilayers is shown in FIG. 2A. The figure illustrates that the thickness tₗ of the low stress interlayer in each bilayer is much less than the thickness tₘ of the main portion of each bilayer. The figure also illustrates that in this particular embodiment, the low-stress interlayer is deposited before the main portion, with the lowest interlayer in the stack deposited directly upon the silicon substrate.

One way of depositing such a configuration of bilayers is by using an ALD process wherein the deposition of the interlayers is achieved by altering process conditions during certain phases of the overall ALD process. It is noted again that residual stress in dielectric films formed via plasma activated ALD processes depends mostly on the deposition temperature and characteristics of the plasma used during the reactive conversion step of the ALD cycle—in particular, plasma RF power, plasma exposure time, and (more generally) the total plasma RF energy applied to the film during the reactive conversion.

Putting it simply, higher temperatures and/or plasma energies lead to films with generally improved properties, but at the cost of higher residual stress, whereas low plasma power generally does not lead to the formation of a high quality film but it does deposit a film with low residual stress. Once again, this is illustrated in Table I and FIGS. 1A-1F. Thus, if one is depositing a high-stress film via a cyclic ALD process—since residual stress may be modulated via temperature and/or plasma energy—one approach for introducing one or more low-stress interlayers is to reduce the plasma power employed during the plasma activation/conversion steps of certain selected cycles of the overall cyclic ALD process. To form a film having 4 reduced-stress bilayers as shown in FIG. 2A, plasma power could be altered during 4 sets of cyclic subsequences, wherein each results in the formation of a low-stress/stress-reducing interlayer. Cyclic ALD processes are described in greater detail below.

It should be appreciated that to deposit reduced-stress films having one or more bilayers, wherein each layer is made up of a main portion and a low-stress interlayer portion, one could view the overall process as composed of two types of ALD cycles—one to deposit the main portions, and one the interlayer portions—the main difference between them being the plasma energy employed during the ALD reactive/conversion step.

Thus, for example, methods for forming reduced-stress dielectric films may include depositing a first reduced-stress bilayer of dielectric film by depositing a main portion, wherein the total RF energy applied, per unit film area, to the main portion while it is being deposited may be greater than about 0.1 Joules/cm², or more particularly greater than about 0.16 Joules/cm², or even more particularly greater than about 0.25 Joules/cm². Likewise the total RF energy applied, per unit film area, to the low-stress portion while it is being deposited may be less than about 0.1 Joules/cm², or more particularly less than about 0.05 Joules/cm²; although it should be understood that the total RF energy applied to the main low-stress portion is less than the total RF energy applied to the main portion.

Similarly, in some embodiments, the RF power level applied to the main portion during the conversion step of its deposition may be more than about 0.5 Watts/cm², or more than about 0.6 Watts/cm², or more than about 0.7 Watts/cm², or even more than about 0.8 Watts/cm²; while the RF power level applied to the low-stress portion during the conversion step of its deposition may be less than about 0.5 Watts/cm², or less than about 0.4 Watts/cm², or less than about 0.3 Watts/cm², or even less than about 0.2 Watts/cm².

Rather than using different RF power levels to create a difference in plasma energy applied to the main and low-stress portions during their deposition, one may apply the reaction-activating plasma for different amounts of time during the deposition of the two different types of film portions. Thus, for instance, RF power may be applied during deposition of the main film portions for more than about 0.2 seconds/cycle, while applied for less than about 0.1 seconds/cycle during deposition of the low-stress portions.

It is also noted that plasma power levels effect film quality and residual stress level in films deposited with other plasma enhanced deposition processes, such as PECVD. Accordingly, adjustment of plasma power could also be used for introducing stress-reducing interlayers into what would otherwise be high-stress films deposited with these other sorts of deposition processes. Moreover, it is noted that other process parameters such as temperature, pressure, plasma composition, reactant gas composition and concentration, etc. may also potentially be adjusted during certain sequences of cycles in a cyclic ALD process (alone or in combination) in order to effect the insertion of one or more low-stress interlayers into the deposited film stack. In principle such modulation may be done in the dose, purge, and plasma-activation/conversion steps, or in some combination of these steps.

Effect of Interlayer Thickness Ratio on Film Properties

The proportion of the total film thickness which is accounted for by the interlayer portions versus that accounted for by the main film portions will have an effect on the total film's overall residual stress level. FIG. 2B shows this effect for the example of the film configuration of FIG. 2A having 4 bilayers (and thus 4 low-stress interlayer portions). In particular, FIG. 2B plots residual compressive stress versus thickness ratio, where the thickness ratio is the ratio of the combined thickness of the 4 interlayer portions relative to the total film thickness. It is seen that for low thickness ratios the compressive stress level declines in roughly inverse proportion to the interlayer proportion, and that the proportion is significant. For example, a thickness ratio of only about 25% reduces compressive stress from −266 MPa to −163 MPa, and a thickness ratio of 33% reduces compressive stress even more, by about 50%. It turns out that the latter is equivalent to the stress level the low stress interlayer would have exhibited had it been deposited by itself (i.e., at 100% thickness ratio, as shown by the far rightmost data point in FIG. 2A). Moreover, it is seen that a stress-neutral film is obtained for a thickness ratio of about 73%, which is remarkable because (again as shown by the far rightmost data point) even the low-stress interlayer by itself is not stress-neutral, or close to it. Hence, this film stress-reducing interlayer technique allows the deposition of a film having a total stress level sₜₒₜ<sₗ, where sₗ is the stress level of the low stress interlayer by itself. Thus, it is noted that, in this particular example, one can do far better (at reducing stress) than the TWA would suggest. Thus, possible thickness ratios which may thus result in a reduced-stress film may include, but are not limited to, 5%, 10%, 25%, 33%, 50%, and 75%, including thickness ratios falling within a range of thickness ratios defined by any pair of the aforementioned thickness ratios. Also note, that in this particular example, the high-stress film portions were deposited at a plasma power level during the ALD conversion step of 2500 W (again, corresponding to a 4-station wafer processing apparatus)—which without interlayer(s) showed a stress level of −266 MPa (far left of the plot)—and that the low-stress interlayer portions were deposited at a plasma power level during the ALD conversion step of 500 W (again, corresponding to 4 stations)—which by themselves (far right of the plot) exhibited a stress level of −139 MPa. A process temperature of 400 C was maintained throughout.

While FIG. 2B provides a specific illustration of how the presence of low-stress interlayers provide a reduction in overall film stress, FIGS. 2C-2G illustrate that this reduction in stress may, for quite a broad range of interlayer thickness ratios, not substantially affect the desirable properties present in the high-stress film without interlayers (i.e., data corresponding to a thickness ratio of 0.0 in FIGS. 2B-2F). For example, FIGS. 2C and 2D plot breakdown voltage and leakage current, respectively, as a function of thickness ratio, again for the 4 bilayer film of FIG. 2A. In each of FIGS. 2B and 2C, these results are overlaid on the compressive stress curve from FIG. 2B. It is seen in these figures that while compressive stress decreases as thickness ratio increases, breakdown voltage and leakage current remain very stable up until a thickness ratio of about 75%, where the these properties finally start to worsen. Thus, below 75% it is found that improvements in stress may be achieved via the presence of low stress interlayers with little if any corresponding degradation in these electrical properties.

Likewise, FIGS. 2E (i) through (v) display capacitance-voltage (C-V) plots for the specific thickness ratios of 0%, 11%, 33%, 73%, and 100%. Again, the figures illustrate that the film's electrical properties are substantially maintained despite the reduction in stress due to the presence of the 4 interlayers. It is only at a thickness ratio of 100% that an undesirable increase in C-V hysteresis is observed.

Finally, FIGS. 2F and 2G display additional plots of the electrical properties of these films deposited with different interlayer thickness ratios. The individual plot traces are labeled by the number of ALD cycles used to deposit the interlayer film portions versus the main film portions. FIG. 2F is a current-voltage plot revealing each deposited film's leakage current level as the horizontal portion of each current-voltage (I-V) trace (see the center of the plot) and its breakdown voltage level as the vertical portion of each trace (toward the left of the plot). Again, the data shows that the film's electrical properties are not severely effected by the presence of the interlayers until the interlayers actually constitute the entire film—i.e., the trace corresponding to the film deposited using 500 interlayer deposition cycles and 0 main film portion deposition cycles. The I-V plot traces do reveal some dependence of breakdown voltage on interlayer film proportion below the 500/0 trace, but the dependence is quite minor. FIG. 2G shows capacitance-voltage (C-V) traces corresponding to the same films and it seen again that there is virtually no undesirable hysteresis present until the film is entirely composed of the interlayer-type film layer (i.e., the 500/0 plot trace). Once again, the conclusion is that one may introduce low-stress interlayers in quite appreciable proportions in order to significantly reduce residual stress levels without significant adverse effects on the film's electrical properties.

Effects of Placement and Number of Low-Stress Interlayers

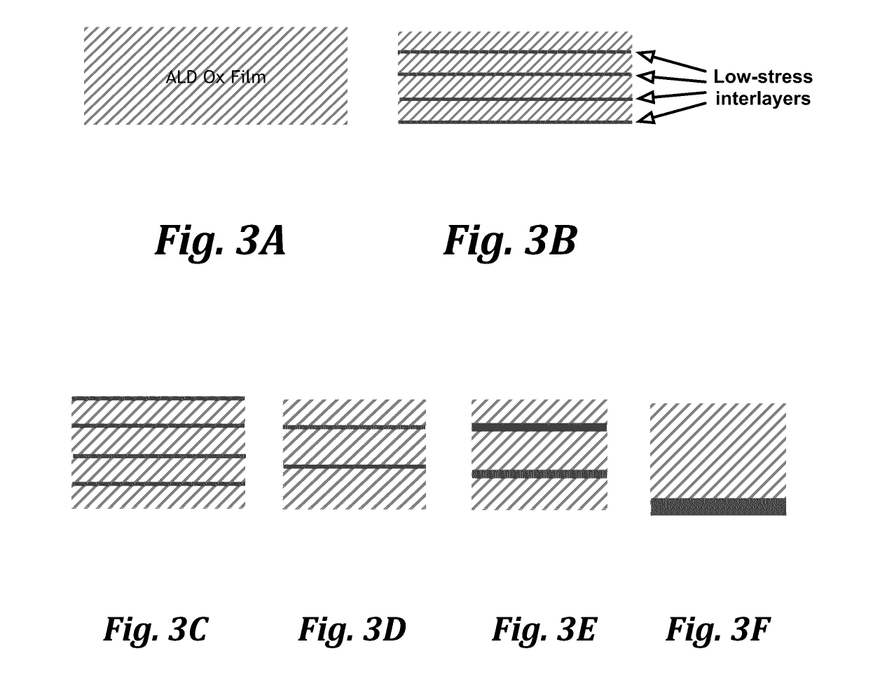

The number of low stress interlayers introduced into the deposited film, as well as their placement (order of introduction) within the film, may also have an effect on the deposited film's residual stress level. For instance, FIGS. 3A-3F display various deposited film structures, FIG. 3A schematically representing a baseline monolithic high-stress film structure (i.e., without any low-stress interlayers), and FIGS. 3B-3F schematically representing different multi-layer film stack structures, each having one or more low-stress interlayers deposited within the layers of high-stress film according to various deposition sequences. In particular, FIG. 3B displays a film stack structure having 4 reduced-stress bilayers, each made up of a main (high-stress) film portion and a low-stress interlayer film portion. In this embodiment, for each reduced-stress bilayer, its low-stress portion is deposited before (below) the main portion. FIG. 3C displays a similar configuration of 4 reduced-stress bilayers, but in this embodiment, for each reduced-stress bilayer, its low-stress portion is deposited after (above) the main portion. FIG. 3D displays a slightly different configuration which could be described as having 2 bilayers—interlayer portions deposited after main portions in each (as in FIG. 3C)—but capped with another layer of the high-stress (main) film. Or, FIG. 3D could be viewed as having 2 bilayers—interlayer portion deposited before main portions in each (as in FIG. 3B)—but deposited after (above) a previously deposited high-stress (main) film portion. FIG. 3E displays a stack structure similar in configuration to FIG. 3D, but shown having each interlayer portion of double the thickness shown in FIG. 3D. Thus, the film in FIG. 3E has the same thickness ratio as the films in FIGS. 3B and 3C, but with the low stress interlayers thickness combined into just 2 bilayers, instead of 4. The film configuration shown in FIG. 3F takes this one step further by combining everything into a single bilayer, but having the same thickness ratio as FIGS. 3B, 3C, and 3E. The reduced-stress film formation methods disclosed herein may be used to deposit films embodying any of these stack structures.

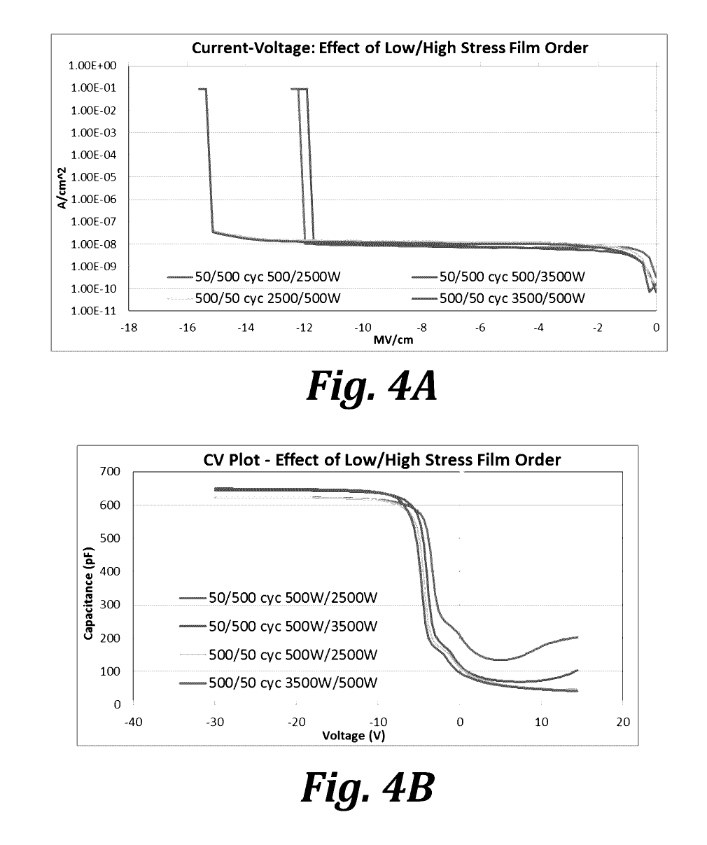

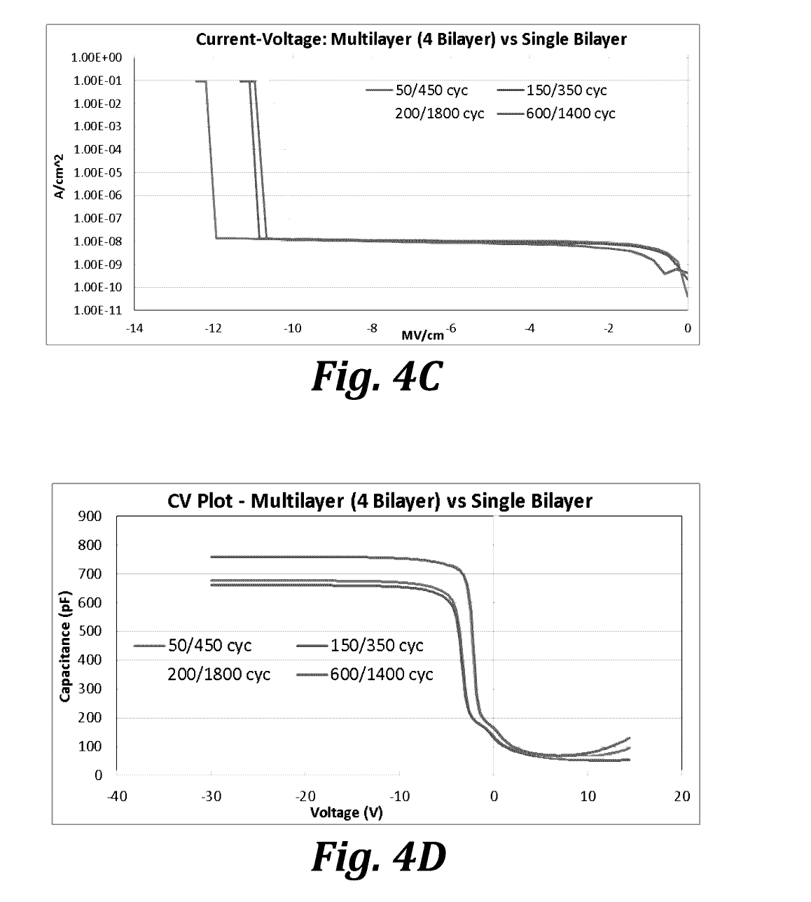

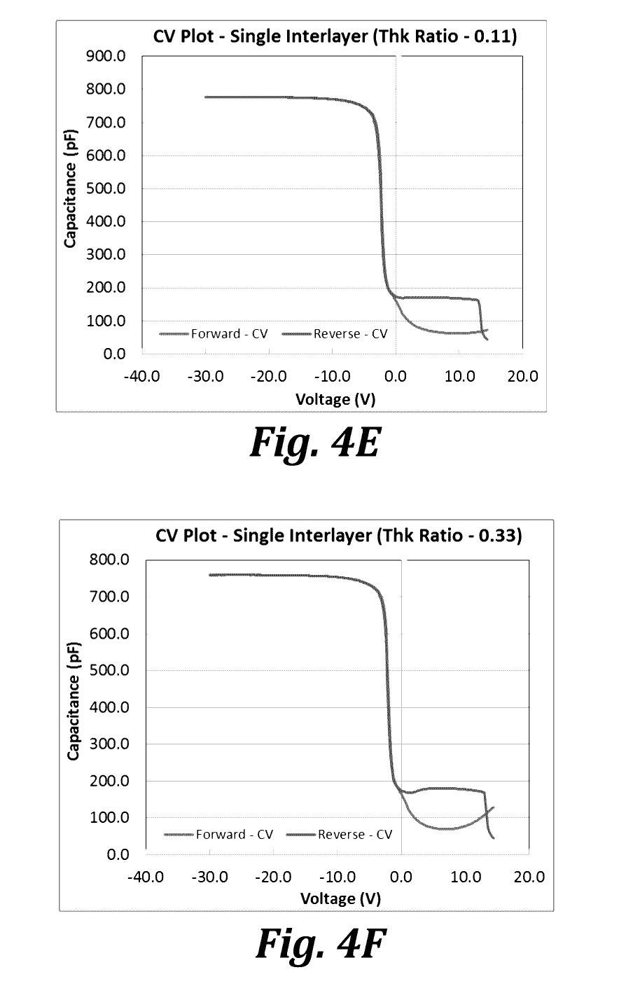

This is useful, because in some cases it has been found that films which have the same thickness ratio, but that have different stack configurations, may exhibit differences in film properties. For instance, FIG. 4A shows the effect of low/high stress film ordering on breakdown voltage; and in FIG. 4B, on capacitance. The results shown correspond to different 4-bilayer films having one of two stack configurations—either the configuration shown in FIG. 3B (interlayer on bottom) or the configuration shown in FIG. 3C (interlayer on top)—and for each of the two stack configurations, a film was deposited using 2500 W plasma power during the ALD conversion step for its main portions, and another was deposited using 3500 W plasma power. The raw data plotted in FIGS. 4A and 4B is listed in Table II.

TABLE II

| | | | | Compressive | | |
|---|---|---|---|---|---|---|
| Process (plasma power (W) for | Thickness | NU % | DepR | Stress | BDV | Leakage Current |
| 4 stations) | (A) | (R/2) | (A/cyc) | (MPa) | (MV/cm) | (A/cm2@ 4 MV/cm) |
| 50 cyc 500 W/500 cyc 2500 W | 1337.0 | 1.78 | 0.608 | −229.5 | −11.98 | 6.93E−09 |
| 500 cyc 2500 W/50 cyc 500 W | 1343.7 | 1.82 | 0.611 | −235.2 | −15.14 | 1.24E−08 |
| 50 cyc 500 W/500 cyc 3500 W | 1292.0 | 1.71 | 0.587 | −263.4 | −11.68 | 6.38E−09 |
| 500 cyc 3500 W/50 cyc 500 W | 1302.8 | 1.71 | 0.592 | −264.4 | −15.13 | 1.01E−08 |

The data in the figures (and the table) reveal that the two stack configurations (essentially, reversing the order of deposition of low/high stress films), has only minor effects on stress, non-uniformity, deposition rate, and leakage current (FIG. 4B). However it is seen that breakdown voltages are improved significantly (FIG. 4A) for the films having the stack configuration with the main (high-stress) film portion deposited before the interlayer (as in FIG. 3C). Thus, in some embodiments, it may be advantageous when forming one or more or all reduced-stress bilayers to deposit the main (high-stress) portion of each bilayer before the low-stress interlayer portion. (Although, there still may be other embodiments where it is more advantageous to deposit the main portion after the interlayer.)

Likewise, the data shown in FIG. 4C investigates the effect on breakdown voltage of altering the number of bilayers—specifically, using a 4-bilayer film (having the stack structure shown in FIG. 3B) versus a 1-bilayer film (having the stack structure shown in FIG. 3F). The 1-bilayer versus 4-bilayer comparison is done for two thickness ratios (0.11 and 0.33). The effect on capacitance (versus voltage) is shown FIG. 4D for the same films. The raw data from these experiments is listed in Table Ill.

TABLE III

| | | | | | Leakage |
|---|---|---|---|---|---|
| Process (plasma | | | Compressive | | Current |
| power (W) for | Thk | NU % | Stress | BDV | (A/cm2@ |
| 4 stations) | Ratio | (R/2) | (MPa) | (MV/cm) | 4 MV/cm) |
| 4 Interlayer | 0.11 | 1.81 | −230.5 | −11.94 | 1.03E−08 |
| (500 W/2500 W) | | | | | |
| 1 Interlayer | 0.11 | 2.44 | −219.5 | −10.24 | 6.21E−09 |
| (500 W/2500 W) | | | | | |
| 4 Interlayer | 0.33 | 1.93 | −135.6 | −10.50 | 3.03E−09 |
| (500 W/2500 W) | | | | | |
| 1 Interlayer | 0.33 | 2.94 | −141.4 | −10.67 | 7.81E−09 |
| (500 W/2500 W) | | | | | |

From these experiments, it is seen that at each thickness ratio (0.11 and 0.33) residual film stress, breakdown voltage, leakage current, and capacitance are comparable between the 1-bilayer and 4-bilayer structures. However, Table III shows that at both thickness ratios, the 4 bilayer structure exhibits substantially improved non-uniformity. Thus, despite the fact that a single low-stress interlayer may lower film stress significantly, in some embodiments, it is preferred to deposit a multi-bilayer structure, for instance, having 2 or 3 or 4 or 5 or 6 or 7 or 8 or more bilayers. Finally, it is noted that for the single bilayer films, the C-V curves shown in FIGS. 4E and 4F—for thickness ratios 0.11 and 0.33, respectively—exhibit little or no hysteresis.

Effects of Interlayer Stress Level on Overall Film Stress

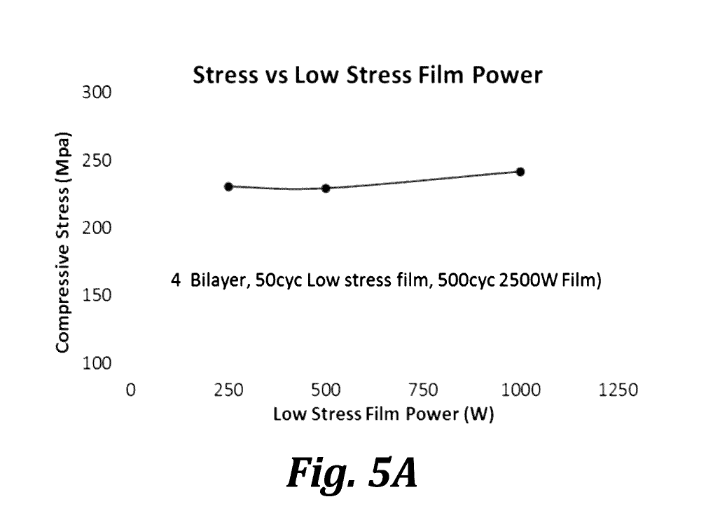

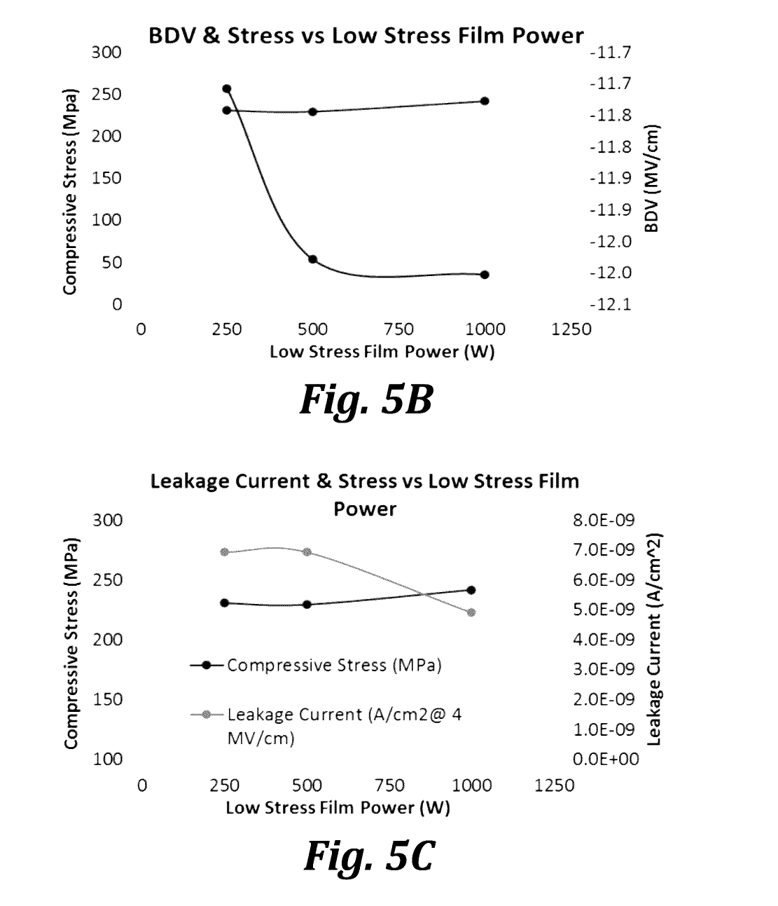

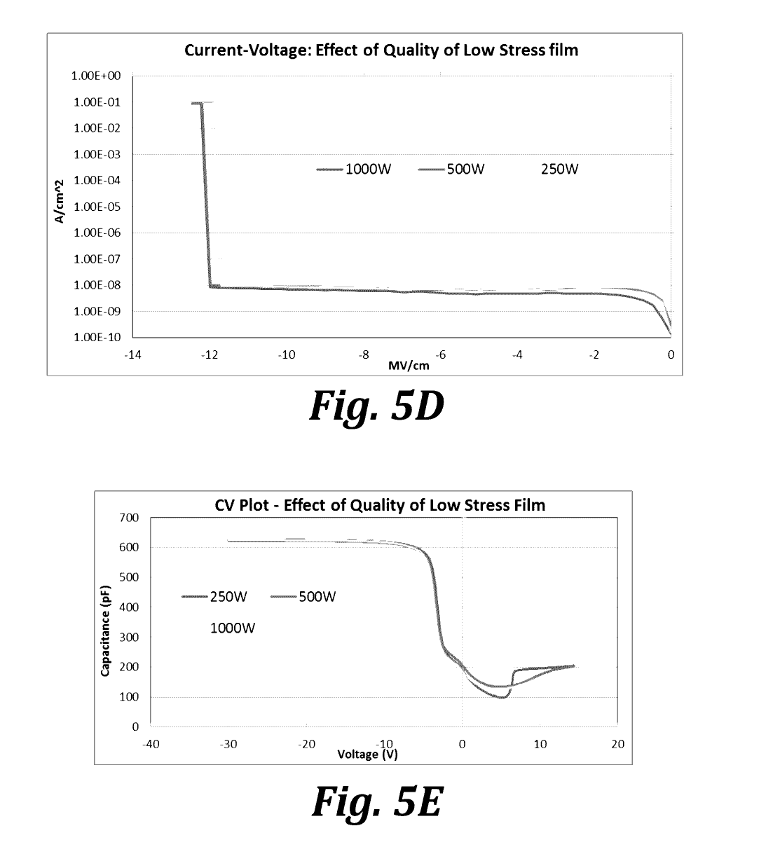

FIGS. 5A-5E investigate the effects of using increased plasma power during the ALD conversion step of the ALD cycles used to deposit the interlayers. The experiments involved a film stack structure having 4 reduced-stress bilayers, each made up of a main (high-stress) film portion (deposited via 500 ALD cycles at 2500 W plasma power divided between 4 stations) and a low-stress interlayer film portion (deposited via 50 ALD cycles at various plasma power wattages). In each of the figures, it is seen that using increased plasma power in the deposition of the low-stress interlayer film portion, increasing from 500 W to 750 W, and from 750 W to 1000 W (again, corresponding to processing 4 wafers in a 4-station processing chamber) has a minimal effect on film properties. As shown in the figures and in Table IV below, these properties include compressive stress, breakdown voltage, leakage current, capacitance (versus voltage), deposition rate (thickness) and non-uniformity. Note that for the breakdown voltage plot (in FIG. 5B) the vertical axis (voltage) ranges from only −12.1 to −11.7 MV/cm.

TABLE IV

| Interlayer | | | |
|---|---|---|---|
| Power (W) | Thickness | NU % | Compressive Stress |
| (4 station) | (A) | (R/2) | (MPa) |
| 250 W | 1334.7 | 1.82 | 230.7 |
| 500 W | 1337.0 | 1.78 | 229.5 |
| 1000 W | 1332.8 | 1.79 | 241.8 |

Film Deposition Via Atomic Layer Deposition (ALD) in Detail

A semiconductor fabrication step employing the ALD technique to form a film of material typically employs multiple sequential cycles of ALD. A single cycle of ALD only deposits a thin film of material (oftentimes only one molecular layer thick). To build up a film of an appreciable desired thickness, multiple ALD cycles can be performed. Hence there exists the concept of an “ALD cycle” which is sequentially repeated.

In brief, a basic “ALD cycle” for forming a single layer of dielectric film on a substrate may include the following steps: (i) film precursor dosing/adsorption, (ii) post-dose removal of unadsorbed precursor, (iii) plasma-activated reaction/conversion of adsorbed precursor, and optionally, (iv) post-reaction removal of desorbed precursor and/or reaction by-product. Operations (i)-(iii)—and in some embodiments also (iv)—therefore constitute a single cycle of ALD which may then be repeated one or more times to deposit additional layers of film on the substrate, and to thereby build up a film of appreciable thickness as desired.

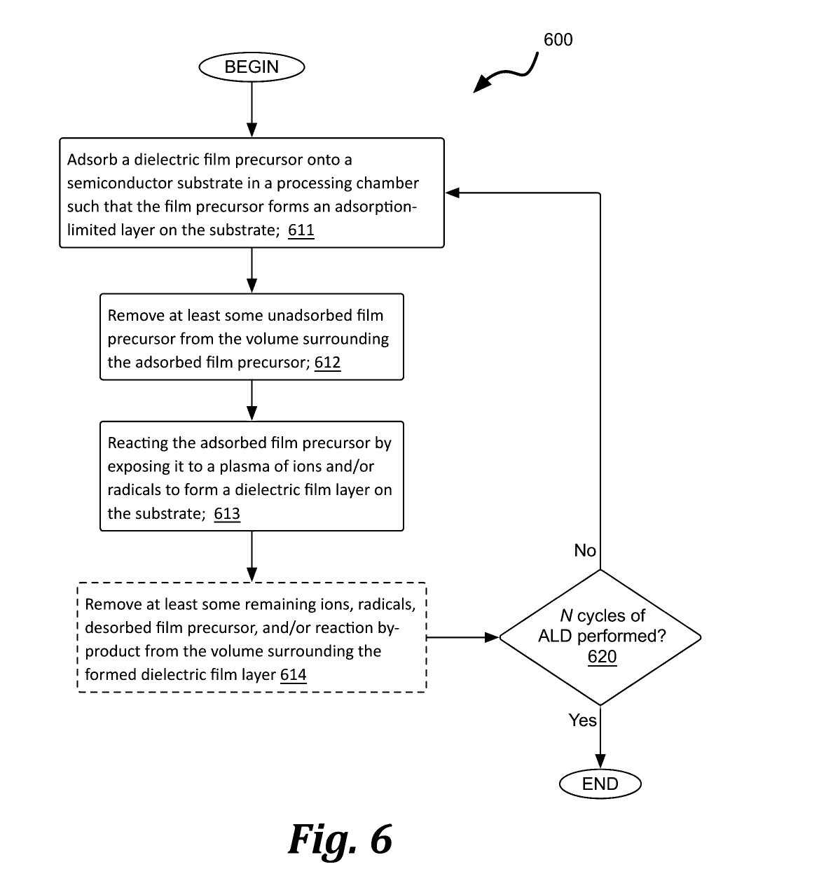

In greater depth, such a basic ALD process sequence for dielectric film deposition is schematically illustrated in by the flowchart of FIG. 6. As shown in the figure, a single ALD cycle may begin with an operation 611 of adsorbing a dielectric film precursor onto a semiconductor substrate in a processing chamber such that the film precursor forms an adsorption-limited layer on the substrate. For deposition of a Si-based dielectric film such as SiOx, SiNx, etc., the film precursor typically contains Si, and thus acts as the Si source for the growing dielectric film. The absorption/dose operation is followed by an operation 612 of removing at least some unadsorbed film precursor from the volume surrounding the adsorbed film precursor. Thereafter, in operation 613, the adsorbed film precursor is reacted by exposing it to a plasma comprising ions and/or radicals of species containing, for example, oxygen (O) or nitrogen (N) (which may oxidize the absorbed dielectric precursor). This then results in the formation of a dielectric film layer on the substrate. Finally, in some embodiments (as indicated by the dashed-line-drawn box in FIG. 6) and depending on the chemistry of the film-forming reaction, operation 613 may be followed by an operation 614 to remove at least some remaining ions, radicals, desorbed film precursor, and/or reaction by-product from the volume surrounding the formed dielectric film layer. Note that in the examples above concerning the use of one or more low stress interlayers to form a reduced-stress dielectric film, the low stress interlayer was formed by varying plasma power in the ALD reacting/conversions step 613 of FIG. 6.

The foregoing sequence of operations 611 through 614 represent a single ALD cycle resulting in the formation of a single layer of dielectric film. However, since a single layer of film formed via ALD is typically very thin—often it is only a single molecule thick—multiple ALD cycles are repeated in sequence to build up a dielectric film of appreciable thickness. Thus, referring again to FIG. 6, if it is desired that a film of say N layers be deposited (or, equivalently, one might say N layers of film), then multiple ALD cycles (operations 611 to 614) are repeated in sequence, and after each ALD cycle concludes with operation 614, in operation 620, it is determined whether N cycles of ALD have been performed. Then, if N cycles have been performed, the film-forming operations conclude, whereas if not, the process sequence returns to operation 611 to begin another cycle of ALD. In so doing, a conformal film of the desired thickness may be deposited.

During step (i) of the ALD cycle just described—i.e., film precursor dosing/adsorption—silicon-containing film precursor may be flowed to the reaction chamber at a rate of between about 1 and 5 sL/m (standard liters per minute), or more particularly between about 3 and 5 sL/m, or still more particularly between about 4 and 5 sL/m, or about 4.5 sL/m. These values correspond to a 4 station reaction chamber designed to handle 300 mm diameter wafers. Flow rates would be adjusted proportionally for reaction chambers with greater or fewer numbers of stations, or for larger or smaller diameter wafers. Of course, even for a fixed number of stations and wafer size, the volume of the reaction chamber also influences the choice of flow rate. Thus, depending on the embodiment, silicon-containing film precursor may be flowed to the reaction chamber such that the precursor has a partial pressure in the chamber of between about 1 and 50 torr, or more particularly between about 10 and 20 torr, or in some embodiments, between about 8 and 12 torr, or about 10 torr. The duration of the flow may be for between about 1 and 15 seconds, or more particularly between about 1 and 5 seconds, or yet more particularly between about 2 and 3 seconds, or for about 2.5 seconds.

Depending on the embodiment, the film precursor adsorbed onto the substrate during step (i), in addition to containing silicon, may include one or more halogens, or two or more halogens (see the description of halosilanes below). Examples of the latter include dichlorosilane, hexachlorodisilane, tetrachlorosilane. In some embodiments, the silicon-containing film precursor adsorbed during step (i) may be selected from the aminosilanes.

During step (ii) of the ALD cycle just described—i.e., the post-dose removal of unadsorbed precursor—the purge may employ an inert purge gas (such as N₂ or Ar) flowed to the reaction chamber at a rate of between about 10 and 40 sL/m for between 1 and 10 seconds, or more particularly for between about 1 and 3 seconds, or for about 2 seconds. Again, these values correspond to a 4 station reaction chamber designed to handle 300 mm diameter wafers. Flow rates would again be adjusted proportionally for reaction chambers with greater or fewer numbers of stations, or for larger or smaller diameter wafers. In some embodiments, this purge may be followed by a pump-to-base (PTB)—i.e., pumping the chamber down to a base pressure, typically as low as is reasonably feasible to achieve. The PTB may be accomplished by directly exposing the reaction chamber to one or more vacuum pumps. In some embodiments, the base pressure may typically be only a few milliTorr (e.g., between about 1 and 20 mTorr).

During step (iii) of the ALD cycle just described—i.e., the plasma-activated reaction/conversion of adsorbed precursor—a plasma is generated which includes, for example, N-containing and/or O-containing ions and/or radicals to which the adsorbed dielectric film precursor is exposed resulting in the surface reaction forming a layer of dielectric film. The plasma is formed by applying RF electromagnetic (EM) radiation to a plasma precursor, which may be ammonia (NH₃), molecular nitrogen gas (N₂), an amine such as t-butyl amine, oxygen gas (O₂), NO, N₂O, etc., or a combination of the foregoing.

However, in some embodiments, prior to generating the plasma, a pre-flow of the plasma precursor (e.g., NH₃, O₂, etc.) is established for between about 0.5 and 10 seconds, or more particularly for between about 4 and 8 seconds, or for about 6 seconds. The flow rate may be between about 1 and 10 sL/m, or more particularly between about 4 and 6 sL/m, or about 3 sL/m, however, again, these values correspond to a chamber with 4 stations for handling 300 mm wafers, and so, depending on the embodiment, the plasma precursor may be flowed to the reaction chamber in a manner so as to establish a partial pressure of the plasma precursor of between about 1.5 and 6 torr, or more particularly between about 1.5 and 3 torr, or about 2 torr.

Still referring to step (iii), after the pre-flow, RF power is switched on to generate the plasma. Viable flows and partial pressures for the plasma precursor during plasma generation may be the same as those just described for pre-flow. RF power for generating the plasma may be between about 100 and 6000 W, or more particularly between about 400 and 5100 W, or yet more particularly between about 900 and 4100 W, or still yet more particularly between about 2500 and 3500, or about 3000 with a frequency of 13.56 MHz (although positive integer multiples of 13.56 MHz such as 27.12 MHz, 40.68 MHz, or 54.24 MHz, and so forth may also be used depending on the embodiment, and some frequency tuning about 13.56 MHz or the multiple thereof may also be employed as described in further detail below). The RF power may remain switched on for between about 0.1 and 6 seconds resulting in a corresponding exposure time of the adsorbed dielectric film precursor to ions and/or radicals of the plasma for between about 0.1 and 6 seconds causing the dielectric film forming surface reaction. More particularly, RF power may be switched on (and the absorbed film precursor exposed to the plasma) for between about 0.5 and 3 seconds, or for between about 0.5 and 2 seconds, or for between about 1 and 2 seconds. Once again, it should be understood that these plasma powers correspond to a chamber having 4 process stations for handling 300 mm diameter wafers. As such, appropriate plasma power densities for step (iii) may be between about 0.035 and 2.2 W/cm² (since, 0.035≈100/(4*π*15²) and 2.2≈6000/(4*π*15²)), and similarly for the other plasma power values and ranges stated above.

In some embodiments, there has been found to be a tradeoff between plasma exposure time and plasma power—i.e., short exposure time works well with high plasma power, long exposure time works well with low plasma power, and intermediate exposure time works well with intermediate plasma power.

As for optional step (iv) of the ALD cycle just described—post-reaction removal of desorbed precursor and/or reaction by-product—removal may be accomplished by purging the chamber with an inert purge gas (e.g., Ar or N₂) at a flow rate of between about 10 and 40 sL/m for between 1 and 10 seconds, or more particularly for between about 1 and 3 seconds, or for about 2 seconds. Once again, the flow rates correspond to a chamber with 4 stations for handling 300 mm diameter wafers and so would be adjusted proportionally for larger or smaller chambers handling greater or fewer numbers of wafers of larger or smaller diameters. In terms of pressure, pressure within the chamber during the purge may be between about 2 and 10 torr, or more particularly between about 4 and 8 torr, or about 6 torr. As with removal step (ii), in some embodiments, a PTB may also be employed during step (iv) to facilitate removal.

Thus, the removing in operations (ii) and (iv) may be done generally via purging, evacuating by pumping down to a base pressure (“pump-to-base”), etc. the volume surrounding the substrate. In some embodiments, these purges may be logically divided into what is referred to herein as a “primary purge” or “burst purge” and a “secondary purge.” (The use of primary/burst and secondary purges are described in detail in U.S. patent application Ser. No. 14/447,203 filed Jul. 30, 2014, titled “METHODS AND APPARATUSES FOR SHOWERHEAD BACKSIDE PARASITIC PLASMA SUPPRESSION IN A SECONDARY PURGE ENABLED ALD SYSTEM,” which is incorporated by reference herein in its entirety for all purposes.)

Additional Details Regarding ALD Techniques and Operations

As discussed above, as devices sizes continue to shrink and ICs move to employing 3-D transistors and other 3-D structures, the ability to deposit a precise amount (thickness) of conformal film—such as, for example, dielectric films of SiOx, SiNx, SiOxNy, SiCxNy, SiCx, TiOx (for different values and combinations of x and y), or other dielectrics—has become increasingly important. As stated, atomic layer deposition (ALD) is one technique for accomplishing conformal film deposition that typically involves multiple cycles of deposition in order to achieve a desired thickness of film.

In contrast with a chemical vapor deposition (CVD) process, where activated gas phase reactions are used to deposit films, ALD processes use surface-mediated deposition reactions to deposit films on a layer-by-layer basis. For instance, in one class of ALD processes, a first film precursor (P1) is introduced in a processing chamber in the gas phase, is exposed to a substrate, and is allowed to adsorb onto the surface of the substrate (typically at a population of surface active sites). Some molecules of P1 may form a condensed phase atop the substrate surface, including chemisorbed species and physisorbed molecules of P1. The volume surrounding the substrate surface is then evacuated to remove gas phase and physisorbed P1 so that only chemisorbed species remain. A second film precursor (P2) may then be introduced into the processing chamber so that some molecules of P2 adsorb to the substrate surface. The volume surrounding the substrate within the processing chamber may again be evacuated, this time to remove unbound P2. Subsequently, energy provided to the substrate (e.g., thermal or plasma energy) activates surface reactions between the adsorbed molecules of P1 and P2, forming a film layer. Finally, the volume surrounding the substrate is again evacuated to remove unreacted P1 and/or P2 and/or reaction by-product, if present, ending a single cycle of ALD.

ALD techniques for depositing conformal films may involve a variety of chemistries, and there are many potential variations on the basic ALD process sequence which may be employed depending on the desired reaction chemistry as well as identity and properties of the deposited film. Many such variations are described in detail in U.S. patent application Ser. No. 13/084,399, filed Apr. 11, 2011, titled “PLASMA ACTIVATED CONFORMAL FILM DEPOSITION” (Attorney Docket No. NOVLP405), U.S. patent application Ser. No. 13/242,084, filed Sep. 23, 2011, titled “PLASMA ACTIVATED CONFORMAL DIELECTRIC FILM DEPOSITION,” now U.S. Pat. No. 8,637,411 (Attorney Docket No. NOVLP427), U.S. patent application Ser. No. 13/224,240, filed Sep. 1, 2011, titled “PLASMA ACTIVATED CONFORMAL DIELECTRIC FILM DEPOSITION” (Attorney Docket No. NOVLP428), and U.S. patent application Ser. No. 13/607,386, filed Sep. 7, 2012, titled “CONFORMAL DOPING VIA PLASMA ACTIVATED ATOMIC LAYER DEPOSITION AND CONFORMAL FILM DEPOSITION” (Attorney Docket No. NOVLP488), each of which is incorporated by reference herein in its entirety for all purposes.

As described in these prior applications, a basic ALD cycle for depositing a single layer of material on a substrate may include: (i) adsorbing a film precursor onto a substrate such that it forms an adsorption-limited layer, (ii) removing unadsorbed precursor from the volume surrounding the adsorbed precursor, (iii) reacting the adsorbed precursor to form a layer of film on the substrate, and (iv) removing desorbed film precursor and/or reaction by-product from the volume surrounding the layer of film formed on the substrate. The removing in operations (ii) and (iv) may be done via purging, evacuating, pumping down to a base pressure (“pump-to-base”), etc. the volume surrounding the substrate. It is noted that this basic ALD sequence of operations (i) through (iv) doesn't necessary involve two chemiadsorbed reactive species P1 and P2 as in the example described above, nor does it even necessarily involve a second reactive species, although these possibilities/options may be employed, depending on the desired deposition chemistries involved. As indicated, many variations are possible. For instance and as indicated above, for the deposition of a silicon-containing dielectric film, a silicon-containing precursor is typically chemiadsorbed (say as P1), and the species which is reacted with it to form the dielectric film may be a N-containing or O-containing species of which the plasma used to cause the reaction in step (iii) is formed. Thus, in some embodiments, a plasma comprising N or O-containing ions and/or radicals is used to provide the N or O atoms in the deposited dielectric film as well as to provide the energy to activate the surface reaction. In other embodiments, it may be envisioned that a silicon-containing precursor may be a first chemiadsorbed species (P1), and a N or O-containing species may be a second chemiadsorbed species (P2), and the plasma applied to both chemiadsorbed species in a step (iii) of such an ALD cycle may then be used to provide activation energy and not necessarily the N or O atoms of the deposited dielectric film. In some embodiments, there is the additional step (iv) of removing any lingering plasma species, desorbed reactants, and/or reactant by-products, etc.

Due to the adsorption-limited nature of ALD, however, a single cycle of ALD only deposits a thin film of material, and typically only a single monolayer of film material. For example, depending on the exposure time of the film precursor dosing operations and the sticking coefficients of the film precursors (to the substrate surface), each ALD cycle may deposit a film layer only about 0.5 to 3 Å thick. Thus, the sequence of operations in a typical ALD cycle—operations (i) through (iv) just described—are generally repeated multiple times in order to form a conformal film of the desired thickness. Thus, in some embodiments, operations (i) through (iv) are repeated consecutively at least 1 time, or at least 2 times, or at least 3 times, or at least 5 times, or at least 7 times, or at least 10 times in a row. An ALD film may be deposited at a rate of about or between 0.1 Å and 2.5 Å per ALD cycle, or about or between 0.2 Å and 2.0 Å per ALD cycle, or about or between 0.3 Å and 1.8 Å per ALD cycle, or about or between 0.5 Å and 1.5 Å per ALD cycle, or about or between 0.1 Å and 1.5 Å per ALD cycle, or about or between 0.2 Å and 1.0 Å per ALD cycle, or about or between 0.3 Å and 1.0 Å per ALD cycle, or about or between 0.5 Å and 1.0 Å per ALD cycle.

In some film forming chemistries, an auxiliary reactant or co-reactant—in addition to what is referred to as the “film precursor”—may also be employed. In certain such embodiments, the auxiliary reactant or co-reactant may be flowed continuously during a subset of steps (i) through (iv) or throughout each of steps (i) through (iv) as they are repeated. In some embodiments, this other reactive chemical species (auxiliary reactant, co-reactant, etc.) may be adsorbed onto the substrate surface with the film precursor prior to its reaction with the film precursor (as in the example involving precursors P1 and P2 described above), however, in other embodiments, it may react with the adsorbed film precursor as it contacts it without prior adsorption onto the surface of the substrate, per se. Also, in some embodiments, operation (iii) of reacting the adsorbed film precursor may involve contacting the adsorbed film precursor with a plasma which, depending on the embodiment, may, in addition to providing activation energy, may provide the auxiliary reactant/co-reactant. For instance, in the processes described above involving dielectric film formation via ALD, the auxiliary reactant/co-reactant may be thought of as the N-containing or O-containing species which is used to form the plasma in step (iii).

In some embodiments, a multi-layer deposited film may include regions/portions of alternating composition formed, for example, by conformally depositing multiple layers sequentially having one composition, and then conformally depositing multiple layers sequentially having another composition, and then potentially repeating and alternating these two sequences. Some of these aspects of deposited ALD films are described, for example, in U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488), which is incorporated by reference herein in its entirety for all purposes. Further examples of conformal films having portions of alternating composition—including films used for doping an underlying target IC structure or substrate region—as well as methods of forming these films, are described in detail in: U.S. patent application Ser. No. 13/084,399, filed Apr. 11, 2011, and titled “PLASMA ACTIVATED CONFORMAL FILM DEPOSITION” (Attorney Docket No. NOVLP405); U.S. patent application Ser. No. 13/242,084, filed Sep. 23, 2011, and titled “PLASMA ACTIVATED CONFORMAL DIELECTRIC FILM DEPOSITION,” now U.S. Pat. No. 8,637,411 (Attorney Docket No. NOVLP427); U.S. patent application Ser. No. 13/224,240, filed Sep. 1, 2011, and titled “PLASMA ACTIVATED CONFORMAL DIELECTRIC FILM DEPOSITION” (Attorney Docket No. NOVLP428); U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488); and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is incorporated by reference herein in its entirety for all purposes.

As detailed in the above referenced specifications, ALD processes may be used to deposit conformal silicon oxide (SiOx) films, silicon carbide (SiC) films, silicon nitride (SiN) films, silicon carbonitride (SiCN) films, or combinations thereof. Silicon-carbon-oxides and silicon-carbon-oxynitrides, and silicon-carbon-nitrides may also be formed in some varieties of ALD-formed films. Methods, techniques, and operations for depositing these types of films are described in detail in U.S. patent application Ser. No. 13/494,836, filed Jun. 12, 2012, titled “REMOTE PLASMA BASED DEPOSITION OF SiOC CLASS OF FILMS,” Attorney Docket No. NOVLP466/NVLS003722; U.S. patent application Ser. No. 13/907,699, filed May 31, 2013, titled “METHOD TO OBTAIN SiC CLASS OF FILMS OF DESIRED COMPOSITION AND FILM PROPERTIES,” Attorney Docket No. LAMRP046/3149; U.S. patent application Ser. No. 14/062,648, titled “GROUND STATE HYDROGEN RADICAL SOURCES FOR CHEMICAL VAPOR DEPOSITION OF SILICON-CARBON-CONTAINING FILMS”; and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is hereby incorporated by reference in its entirety and for all purposes.

Multiple ALD cycles may be repeated to build up stacks of conformal layers. In some embodiments, each layer may have substantially the same composition whereas in other embodiments, sequentially ALD deposited layers may have differing compositions, or in certain such embodiments, the composition may alternate from layer to layer or there may be a repeating sequence of layers having different compositions, as described above. Thus, depending on the embodiment, certain stack engineering concepts, such as those disclosed in the patent applications listed and incorporated by reference above (U.S. patent application Ser. Nos. 13/084,399, 13/242,084, and 13/224,240) may be used to modulate boron, phosphorus, or arsenic concentration in these films.

Film-Forming ALD Chemistries

Deposition of dielectric films may utilize one or more silicon-containing film precursors which may be selected from a variety of compounds. Suitable precursors may include organo-silicon reactants selected and supplied to provide desired composition properties, and in some cases, physical or electronic properties. Examples of silicon-containing reactants/film-precursors may include silanes, alkyl silanes, siloxanes, alkoxysilanes, halosilanes, and aminosilanes, among others.

Regarding the silanes, non-limiting examples which may, in some embodiments, be used to form SiN films include silane (SiH₄), disilane (Si₂H₆), trisilane, and higher silanes.

Alkylsilanes—silicon-containing compounds having one or more silicon atom(s) bonded to one or more alkyl groups and/or hydrogen atoms—may also, in some embodiments, be used to form SiN films. Depending on the embodiment, the silicon atom(s) may be bonded to 4 alkyl groups, or 3 alkyl groups and a hydrogen, or 2 alkyl groups and 2 hydrogens, or 1 alkyl group and 3 hydrogens. Possible alkyl groups which may be selected include, but are not limited to, the Me, Et, i-Pr, n-Pr, and t-butyl functional groups. Specific examples of alkylsilanes suitable for use as film-precursors may include, but are not limited to, methylsilane (H₃SiCH₃), ethylsilane, isopropylsilane, t-butylsilane, dimethylsilane (H₂Si(CH₃)₂), trimethylsilane (HSi(CH₃)₃), tetramethylsilane (Si(CH₃)₄), diethylsilane, triethylsilane, di-t-butylsilane, allylsilane, sec-butylsilane, thexylsilane, isoamylsilane, t-butyldisilane, and di-t-butyldisilane.

Additionally, higher-order silanes may be used in place of monosilanes. In silicon compounds having multiple silicon atoms where a silicon atom is bonded to silicon atom, the number of other substituents on each is reduced by one. An example of one such disilane from the alkyl silane class is hexamethyldisilane (HMDS). Another example of a disilane from the alkyl silane class can include pentamethyldisilane (PMDS), which can be used to form SiC films. In some embodiments, one of the silicon atoms can have a carbon-containing or alkoxy-containing group exclusively attached to it, and one of the silicon atoms can have a hydrogen atom exclusively attached to it. Other types of alkyl silanes can include alkylcarbosilanes. Alkylcarbosilanes can have a branched polymeric structure with a carbon bonded to a silicon atom as well as alkyl groups bonded to a silicon atom. Examples include dimethyl trimethylsilyl methane (DTMSM) and bis-dimethylsilyl ethane (BDMSE). Still other types of alkyl silanes can include silazanes and alkyldisilazanes. Alkyldisilazanes include silizanes and alkyl groups bonded to two silicon atoms. An example includes 1,1,3,3-tetramethyldisilazane (TMDSN). In some embodiments, TMDSN can form SiCN films.

Halosilanes—silicon-containing compounds having one or more silicon atom(s) bonded to one or more halogen atoms—may also, in some embodiments, be used to form SiN films. Depending on the embodiment, the silicon atom(s) may be bonded to 4 halogen atoms, or 3 halogen atoms, or 2 halogen atoms, or 1 halogen atom. Iodosilanes, bromosilanes, chlorosilanes, and fluorosilanes may be suitable for use as film-precursors. Although halosilanes, particularly fluorosilanes, may form reactive halide species that can etch silicon materials, in certain embodiments described herein, the silicon-containing reactant is not present when a plasma is struck. Specific examples of chlorosilanes suitable for use as film-precursors include, but are not limited to, tetrachlorosilane (SiCl₄), trichlorosilane (HSiCl₃), dichlorosilane (H₂SiCl₂), monochlorosilane (ClSiH₃), hexachlorodisilane, chloroallylsilane, chloromethylsilane, dichloromethylsilane (SiHCH₃Cl₂), chlorodimethylsilane, chloroethylsilane, t-butylchlorosilane, di-t-butylchlorosilane, chloroisopropylsilane, chloro-sec-butylsilane, t-butyldimethylchlorosilane, and ethyldimethylchlorosilane. Specific examples of iodosilanes, bromosilanes, and fluorosilanes include, but are not limited to, compounds similar in molecular structure to these chlorine containing compounds but having, in place of the chorine atom(s), either iodine, bromine, or fluorine atom(s), respectively. For instance, the bromosilane corresponding to trichlorosilane (HSiCl₃) is tribromosilane (HSiBr₃).

Aminosilanes—silicon-containing compounds having one or more silicon atom(s) bonded to one or more amine groups—may also, in some embodiments, be used to form SiN films. Depending on the embodiment, the silicon atom(s) may be bonded to 4 amine groups, or 3 amine groups, or 2 amine groups, or 1 amine group. For instance, a particular film-precursor having 2 amine groups and 2 hydrogen atoms bonded to a central silicon atom is BTBAS (bis-t-butylaminosilane, SiH₂(NHC(CH₃)₃)₂). Other specific examples of aminosilanes suitable for use as film-precursors include, but are not limited to, mono-, di-, tri-, and tetra-aminosilane (H₃SiNH₂, H₂Si(NH₂)₂, HSi(NH₂)₃, and Si(NH₂)₄, respectively). Substituted mono-, di-, tri-, and tetra-aminosilanes may also serve as suitable film-precursors including, but not limited to, such compounds having their amine group substituted with the Me, Et, i-Pr, n-Pr, and t-butyl functional groups. Specific examples include t-butylaminosilane, methylaminosilane, t-butylsilanamine, n-tert-butyltrimethylsilyiamine, t-butyl silylcarbamate, SiHCH₃(N(CH₃)₂)₂, SiH(N(CH₃)_{Z})₃, SiHCl(N(CH₃)₂)₂, Si(CH₃)₂(NH₂)₂, (Si(CH₃)₂NH)₃, (NR)₂Si(CH₃)₂ (where R is either a hydrogen or is selected from the Me, Et, i-Pr, n-Pr, and t-butyl functional groups), and trisilylamine (N(SiH₃)₃). Other specific examples include dimethylamino, bis-dimethylamino methylsilane (BDMAMS), and tris-dimethylamino silane (TDMAS), 2,2-bis(dimethylamino)-4,4-di methyl-2,4-disila penta ne, 2,2,4-trimethyl-4-dimethylamino-3,4-disilapentane, dimethylaminodimethylsilane, bis(dimethylamino)methylsilane, and tris(dimethylamino)silane. 1,1,3,3-tetramethyldisilazane is a non-limiting example of a silazane.

For the deposition of a silicon-containing dielectric film, an appropriate silicon-containing reactant/film-precursor, such as those described above, may be used in conjunction with a N-containing or O-containing co-reactant. Non-limiting examples of nitrogen-containing co-reactants which may be used include ammonia, hydrazine, amines such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing co-reactant contains at least one nitrogen, but may also contain heteroatoms other than nitrogen. Thus, for example, hydroxylamine, t-butyloxycarbonyl amine, and N-t-butyl hydroxylamine are considered nitrogen-containing reactants. In some embodiments, the N-containing reactant may be N₂. In some embodiments, the N-containing co-reactant may be used as a species in an ionized or free-radical plasma in order to activate the film-forming surface reaction. In certain such embodiments employing a plasma based on a N-containing co-reactant, referred N-containing co-reactants include NH₃, N₂, and the amines, specifically t-butyl amine.

Finally, it is noted that because multiple ALD cycles may be repeated to build up stacks of conformal layers, in some embodiments, each layer may have substantially the same composition whereas in other embodiments, sequentially ALD deposited layers may have differing compositions, such as when low-stress interlayers are employed, or in certain embodiments, the composition may alternate from layer to layer or there may be a repeating sequence of layers having different compositions, again such as when low-stress interlayers are employed.

Substrate Processing Apparatuses

The methods described herein may be performed with any suitable semiconductor substrate processing apparatus. A suitable apparatus includes hardware for accomplishing the process operations and a system controller having instructions for controlling process operations in accordance with the various dielectric film forming ALD methodologies and residual film stress reducing techniques disclosed herein. In some embodiments, the hardware may include one or more process stations included in a multi-station substrate processing tool, and a controller having (or having access to) machine-readable instructions for controlling process operations in accordance with the film forming techniques disclosed herein.

Thus, in some embodiments, an apparatus suitable for depositing reduced-stress dielectric films on semiconductor substrates may include a processing chamber, a substrate holder in the processing chamber, one or more gas inlets for flowing gases into the processing chamber, a vacuum source for removing gases from the processing chamber, a plasma generator for generating plasmas within the processing chamber, and one or more controllers comprising machine-readable instructions for operating the one or more gas inlets, vacuum source, and plasma generator to deposit dielectric film layers onto semiconductor substrates. Said instructions executed by the controller may include instructions for performing ALD operations (i) though (vi) as described above, and instructions for repeating ALD operations (i) through (vi) multiple times to form multiple layers of reduced-stress film, and instructions for varying the specific process conditions during operations (i) through (vi), or a subset thereof, over various subsequences of consecutive cycles in order to create the multi-layered stacks of reduced stress film having bilayers which combine low-stress interlayer portions with a main (high-stress) film portions. Suitable system controllers having said instructions for implementing said methods are described in further detail below.

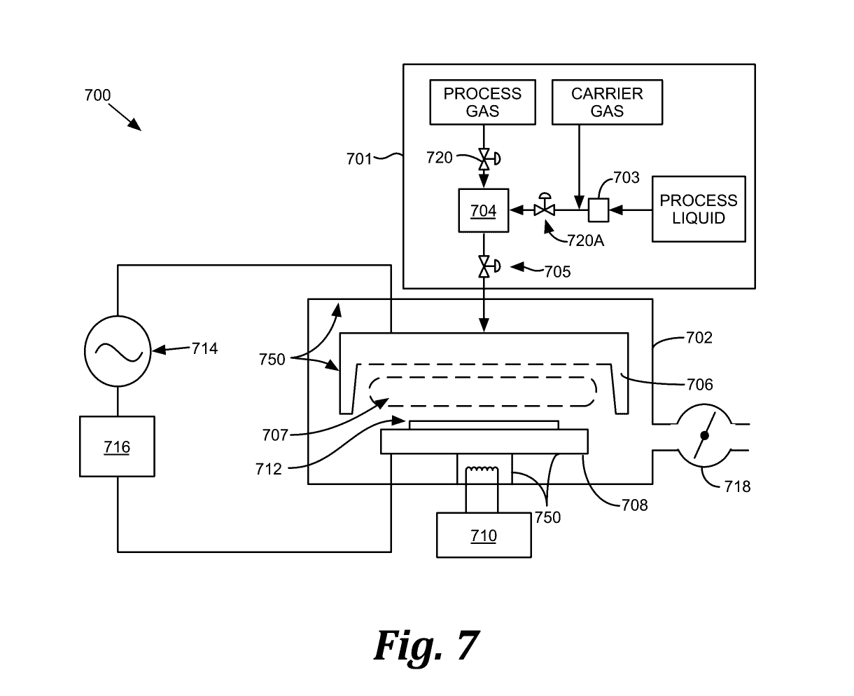

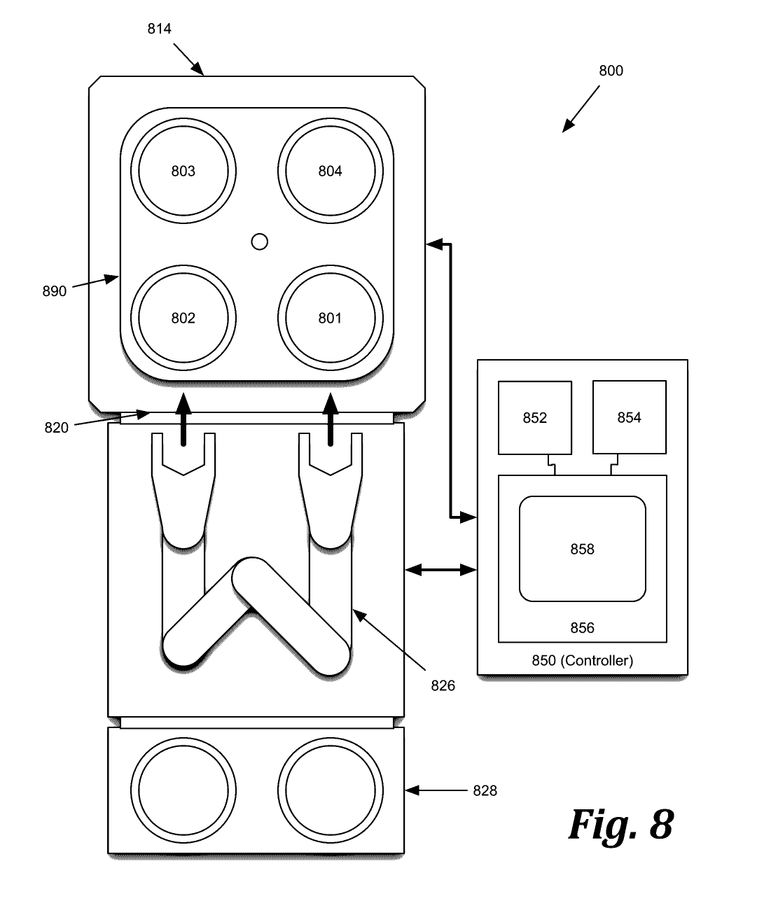

Accordingly, FIG. 7 schematically illustrates an embodiment of a substrate processing apparatus 700 for performing the ALD techniques disclosed herein. Processing apparatus 700 is depicted as having a process chamber body 702 for maintaining a low-pressure environment which, for simplicity, is depicted as hosting a standalone process station. However, it will be appreciated that a plurality of process stations may be included in a common process tool environment—e.g., within a common reaction chamber—as described herein. For example, FIG. 6 depicts an embodiment of a multi-station processing tool. Further, it will be appreciated that, in some embodiments, one or more hardware parameters of processing apparatus 700/600, including those discussed in detail above, may be adjusted programmatically by one or more system controllers.

Referring again to FIG. 7, processing chamber 702 of apparatus 700 has a single substrate holder 708 in an interior volume which may be maintained under vacuum by vacuum pump 718. Also fluidically coupled to the chamber for the delivery of (for example) film precursors, carrier and/or purge and/or process gases, secondary/co-reactants, etc. is gas delivery system 701 and showerhead 706. Equipment for generating a plasma within the processing chamber is also shown in FIG. 7 and will be descried in further detail below. In any event, as it is described in detail below, the apparatus schematically illustrated in FIG. 7 provides the basic equipment for performing film deposition operations such as ALD on semiconductor substrates.

Process station 700 fluidly communicates with reactant delivery system 701 for delivering process gases to a distribution showerhead 706. Reactant delivery system 701 includes a mixing vessel 704 for blending and/or conditioning process gases for delivery to showerhead 706. One or more mixing vessel inlet valves 720 may control introduction of process gases to mixing vessel 704.

Some reactants may be stored in liquid form prior to vaporization and subsequent delivery to the process chamber 702. The embodiment of FIG. 7 includes a vaporization point 703 for vaporizing liquid reactant to be supplied to mixing vessel 704. In some embodiments, vaporization point 703 may be a heated liquid injection module. In some embodiments, vaporization point 703 may be a heated vaporizer. The saturated reactant vapor produced from such modules/vaporizers may condense in downstream delivery piping when adequate controls are not in place (e.g., when no helium is used in vaporizing/atomizing the liquid reactant). Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat treated. In some examples, mixing vessel 704 may also be heat treated. In one non-limiting example, piping downstream of vaporization point 703 has an increasing temperature profile extending from approximately 100° C. to approximately 150° C. at mixing vessel 704.

As mentioned, in some embodiments the vaporization point 703 may be a heated liquid injection module (“liquid injector” for short). Such a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 703. In one scenario, a liquid injector may be mounted directly to mixing vessel 704. In another scenario, a liquid injector may be mounted directly to showerhead 706.

In some embodiments, a liquid flow controller (LFC) upstream of vaporization point 703 may be provided for controlling a mass flow of liquid for vaporization and delivery to processing chamber 702. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 706 distributes process gases and/or reactants (e.g., film precursors) toward substrate 712 at the process station, the flow of which is controlled by one or more valves upstream from the showerhead (e.g., valves 720, 720A, 705). In the embodiment shown in FIG. 7, the substrate 712 is located beneath showerhead 706, and is shown resting on a pedestal 108. It will be appreciated that showerhead may have any suitable shape, and may have any suitable number and arrangement of ports for distributing processes gases to the substrate.

In some embodiments, a microvolume 707 is located beneath showerhead 706. Performing an ALD process in a microvolume in the process station near the substrate rather than in the entire volume of a processing chamber may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters.

In some embodiments, pedestal 708 may be raised or lowered to expose the substrate to microvolume 707 and/or to vary a volume of microvolume 707. For example, in a substrate transfer phase, pedestal may be lowered to allow substrate to be loaded onto the pedestal. During a deposition on substrate process phase, pedestal may be raised to position the substrate within microvolume 707. In some embodiments, said microvolume may completely enclose the substrate as well as a portion of pedestal to create a region of high flow impedance during a deposition process.

Optionally, pedestal 708 may be lowered and/or raised during portions the deposition process to modulate process pressure, reactant concentration, etc. within microvolume 707. In one scenario where processing chamber body 702 remains at a base pressure during the process, lowering the pedestal may allow said microvolume to be evacuated. Example ratios of microvolume to process chamber volume include, but are not limited to, volume ratios between 1:500 and 1:10. It will be appreciated that, in some embodiments, pedestal height may be adjusted programmatically by a suitable system controller.

In another scenario, adjusting a height of pedestal may allow a plasma density to be varied during plasma activation and/or treatment cycles included, for example, in an ALD or CVD process. At the conclusion of a deposition process phase, pedestal may be lowered during another substrate transfer phase to allow removal of substrate from pedestal.

While the example microvolume variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of the pedestal and/or the showerhead may be varied by any suitable mechanism within the scope of the present disclosure. In some embodiments, the pedestal may include a rotational axis for rotating an orientation of the substrate. It will be appreciated that, in some embodiments, one or more of these example adjustments may be performed programmatically by one or more suitable system controllers having machine-readable instructions for performing all or a subset of the foregoing operations.

Returning to the embodiment shown in FIG. 7, showerhead 706 and pedestal 708 may electrically communicate with RF power supply 714 and matching network 716 for powering a plasma generated within the processing chamber. In some embodiments, the plasma energy may be controlled (e.g., via the system controller having appropriate machine-readable instructions) by controlling one or more of a process station pressure, a gas concentration, an RF power level, the frequency of the RF power, and a plasma power pulse timing. For example, RF power supply 714 and matching network 716 may be operated at any suitable power to form a plasma having a desired composition of ions and/or radical species. Various examples of suitable plasma powers—in terms of the RF power level set in the plasma power generator as well as the plasma energy density in the chamber—are described above and accordingly depend on the particular methodology being employed. Depending on the embodiment, RF power supply 714 may provide RF power of any suitable frequency for the processing method being performed. In some embodiments, RF power supply 714 may be configured to control high-frequency (HF) RF power and low-frequency (LF) RF power sources independently of one another. Low-frequencies generated by an RF power source may range from between about 50 kHz and 500 kHz, depending on the embodiment. High-frequencies generated by an RF power source may range from between about 1.8 MHz and 2.45 GHz, depending on the embodiment. It will be appreciated that any suitable parameter may be modulated discretely or continuously to provide plasma energy for the surface reactions. In some embodiments, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy (OES) sensors. In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma activation phase may be included in a corresponding plasma activation recipe phase of a process recipe. In some cases, process recipe phases may be sequentially arranged, so that all instructions for a process phase are executed concurrently with that process phase. In some embodiments, instructions for setting one or more plasma parameters may be included in a recipe phase preceding a plasma process phase. For example, a first recipe phase may include instructions for setting a flow rate of an inert gas (e.g., helium) and/or a reactant gas (e.g., NH₃), instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasmas may be struck and maintained on the order of a few seconds or more. In some deposition processes, plasmas may be struck and maintained for much shorter durations. The chosen duration depends on the nature and purpose of the plasma being generated. Suitable plasma durations and substrate exposure times are indicated above with respect to the particular film deposition techniques disclosed herein. It is noted that very short RF plasma durations may accordingly require very quick stabilization of the plasma. To accomplish this, the plasma generator may be configured such that the impedance match is preset to a particular voltage, while the frequency is allowed to float. Conventionally, high-frequency plasmas are generated at an RF frequency set to about 13.56 MHz, however in some configurations the frequency may be allowed to float to a value that is different from this standard value. By permitting the frequency to float while fixing the impedance match to a predetermined voltage, the plasma can stabilize much more quickly, a result which may be important when using the very short plasma durations sometimes associated with ALD cycles.

In certain embodiments, multiples of the standard HF value of 13.56 MHz may be used to generate even higher frequency plasmas. As when the standard value of 13.56 MHz is used, HF radiation generated at a higher frequency multiple of 13.56 MHz may also be allowed to float around the exact value of the multiple. Multiples of 13.56 MHz which may be used, depending on the embodiment, include 27.12 MHz (=2*13.56 MHz), 40.68 MHz (=3*13.56 MHz), 54.24 MHz (=4*13.56 MHz), and so forth. The frequency tuning about the multiple of 13.56 MHz may include frequency variation of about +/−1 Mhz, or more particularly, of about +/−0.5 MHz. Higher RF frequencies result in a more energetic plasma having higher density, lower sheet voltages, and less ion bombardment and directionality which tends to be beneficial when depositing onto high aspect ratio 3D structures.

In some embodiments, pedestal 708 may be temperature controlled via heater 710. Further, in some embodiments, pressure control for processing apparatus 700 may be provided by one or more valve-operated vacuum sources such as butterfly valve 718. As shown in the embodiment of FIG. 7, butterfly valve 718 throttles a vacuum provided by a downstream vacuum pump (not shown). However, in some embodiments, pressure control of processing apparatus 700 may also be adjusted by varying a flow rate of one or more gases introduced to processing chamber 702. In some embodiments, the one or more valve-operated vacuum sources—such as butterfly valve 718—may be used for removing film precursor from the volumes surrounding the process stations during the appropriate ALD operational phases.

While in some circumstances a substrate processing apparatus like that of FIG. 7 may be sufficient, when time-consuming film deposition operations are involved, it may be advantageous to increase substrate processing throughput by performing multiple deposition operations in parallel on multiple semiconductor substrates simultaneously. For this purpose, a multi-station substrate processing apparatus may be employed like that schematically illustrated in FIG. 8. The substrate processing apparatus 800 of FIG. 8, still employs a single substrate processing chamber 814, however, within the single interior volume defined by the walls of the processing chamber, are multiple substrate process stations, each of which may be used to perform processing operations on a substrate held in a substrate holder at that process station. Note that in some embodiments, by maintaining multiple stations in a common low-pressure environment, defects caused by vacuum breaks between film deposition processes performed at the various stations may be avoided.

In this particular embodiment, the multi-station substrate processing apparatus 800 is shown having 4 process stations 801, 802, 803, and 804. The apparatus also employs a substrate loading device, in this case substrate handler robot 826 configured to move substrates from a cassette loaded from a pod 828, through atmospheric port 820, into the processing chamber 814, and finally onto one or more process stations, specifically, in this case, process stations 801 and 802. Also present is substrate carousel 890 serving as a substrate transferring device, in this case, for transferring substrates between the various process stations 801, 802, 803, and 804.

In the embodiment shown in FIG. 8, the substrate loading device is depicted as substrate handler robot 826 having 2 arms for substrate manipulation, and so, as depicted, it could load substrates at both stations 801 and 802 (perhaps simultaneously, or perhaps sequentially). Then, after loading at stations 801 and 802, the substrate transferring device, carousel 890 depicted in FIG. 8, can do a 180 degree rotation (about its central axis, which is substantially perpendicular to the plane of the substrates (coming out of the page), and substantially equidistant between the substrates) to transfer the two substrates from stations 801 and 802 to stations 803 and 804. At this point, handler robot 826 can load 2 new substrates at stations 801 and 802, completing the loading process. To unload, these steps can be reversed, except that if multiple sets of 4 wafers are to be processed, each unloading of 2 substrates by handler robot 826 would be accompanied by the loading of 2 new substrates prior to rotating the transferring carousel 890 by 180 degrees. Analogously, a one-armed handler robot configured to place substrates at just 1 station, say 801, would be used in a 4 step load process accompanied by 4 rotations of carousel 890 by 90 degrees to load substrates at all 4 stations. It is noted that while FIG. 8 depicts a two-armed substrate handler robot 826 as an example of a substrate loading device, and a carousel 890 as an example of a substrate transferring device, it will be appreciated that other types of suitable substrate loading and transferring devices may be employed as well.

Other similar multi-station processing apparatuses may have more or fewer processing stations depending on the embodiment and, for instance, the desired level of parallel wafer processing, size/space constraints, cost constraints, etc. Also shown in FIG. 8 and described in greater detail below is system controller 850 which controls the operation of the substrate processing apparatus to accomplish the various ALD film forming methodologies disclosed herein.

Note that various efficiencies may be achieved through the use of a multi-station substrate processing apparatus like that shown in FIG. 8 with respect to both equipment cost and operational expenses. For instance, a single vacuum pump (not shown in FIG. 8, but e.g. 518 in FIG. 5) may be used to evacuate spent process gases, create a single high-vacuum environment, etc. with respect to all 4 process stations. Likewise, in some embodiments, a single showerhead may be shared amongst all processing stations within a single processing chamber.

However, in other embodiments, each process station may have its own dedicated showerhead for gas delivery (see, e.g., 706 in FIG. 7), although in certain such embodiments a common gas delivery system may be employed (e.g., 701 in FIG. 7). In embodiments having a dedicated showerhead per process station, each may have its temperature individually adjusted and/or controlled. For instance, each showerhead may be temperature adjusted relative to the substrate to which it delivers gases, or relative to the substrate holder with which it is associated, etc. By the same measure, in embodiments where substrate holders are actively temperature controlled/adjusted, via heating and/or cooling for instance, the temperature of each substrate holder may be individually adjusted.

Other hardware elements which may be shared amongst process stations or multiply present and individually dedicated per process station include certain elements of the plasma generator equipment. All process stations may share a common plasma power supply, for example, but, on the other hand, if dedicated showerheads are present, and if they are used to apply plasma-generating electrical potentials then these represent elements of the plasma generating hardware which are individually dedicated to the different process stations. Once again, each of these process station-specific showerheads may have its temperature individually adjusted according to, for example, differences in the thermal properties of the specific process stations and the particulars of the ALD processes being used.

Of course, it is to be understood that such efficiencies may also be achieved to a greater or lesser extent by using more or fewer numbers of process stations per processing chamber. Thus, while the depicted processing chamber 814 comprises 4 process stations, it will be understood that a processing chamber according to the present disclosure may have any suitable number of stations. For example, in some embodiments, a processing chamber may have 1, or 2, or 3, or 4, or 5, or 6, or 7, or 8, or 9, or 10, or 11, or 12, or 13, or 14, or 15, or 16, or more process stations (or a set of embodiments may be described as having a number of process stations per reaction chamber within a range defined by any pair of the foregoing values, such as having 2 to 6 process stations per reaction chamber, or 4 to 8 process stations per reaction chamber, or 8 to 16 process stations per reaction chamber, etc.).

Moreover, it should be understood that the various process stations within a common processing chamber may be used for duplicate parallel processing operations or differing processing operations, depending on the embodiment. For example, in some embodiments, some process stations may be dedicated to an ALD process mode while others are dedicated to a CVD process mode, while still others may be switchable between an ALD process mode and a CVD process mode.

System Controllers

FIG. 8 also depicts an embodiment of a system controller 850 employed to control process conditions and hardware states of process tool 800 and its process stations. System controller 850 may include one or more memory devices 856, one or more mass storage devices 854, and one or more processors 852. Processor 852 may include one or more CPUs, ASICs, general-purpose computer(s) and/or specific purpose computer(s), one or more analog and/or digital input/output connection(s), one or more stepper motor controller board(s), etc.

In some embodiments, system controller 850 controls some or all of the operations of process tool 800 including the operations of its individual process stations. System controller 850 may execute machine-readable system control instructions 858 on processor 852—the system control instructions 858, in some embodiments, loaded into memory device 856 from mass storage device 854. System control instructions 858 may include instructions for controlling the timing, mixture of gaseous and liquid reactants, chamber and/or station pressure, chamber and/or station temperature, wafer temperature, target power levels, RF power levels, RF exposure time, substrate pedestal, chuck, and/or susceptor position, and other parameters of a particular process performed by process tool 800. These processes may include various types of processes including, but not limited to, processes related to deposition of film on substrates. Thus, the machine-readable instructions 858 executed by system controller 850 may include instructions for performing ALD operations (i) though (vi) as described above, and instructions for repeating ALD operations (i) through (vi) multiple times, and for varying process conditions within certain sequences of cycles to form a multilayered reduced stress film.

Moreover, to accomplish the reduced-stress film-forming methodologies disclosed herein, the machine-readable instructions 858 executed by system controller 850 may included instructions for depositing a first reduced-stress bilayer of the dielectric film.

In some embodiments, the instructions for depositing the reduced-stress bilayer may include instructions for depositing a main portion having a thickness tₘ, and stress level sₘ; and instructions for depositing a low stress portion having a thickness tₗ and stress level sₗ where sₗ<sₘ, wherein the first reduced-stress bilayer is characterized by an overall stress level sₜₒₜ, and wherein sₜₒₜ<90%*(sₘ*tₘ+sₗ*tₗ)/(tₘ+tₗ).

In some embodiments, the instructions for depositing the reduced-stress bilayer may include instructions for depositing a main portion having a thickness tₘ, and stress level sₘ; and instructions for depositing a low stress portion having a thickness tₗ and stress level sₗ where sₗ<sₘ; wherein the first reduced-stress bilayer is characterized by an overall stress level sₜₒₜ<90%*sₘ, and wherein the main and low stress portions of the reduced-stress bilayer have substantially the same chemical composition within a margin of 5.0 mole percent per unit volume for each individual elemental component.

In some embodiments, the instructions for depositing the reduced-stress bilayer may include instructions for depositing a main portion having a thickness tₘ, stress level sₘ, leakage current Iₘ, and breakdown voltage Vₘ; and instructions for depositing a low stress portion having a thickness tₗ, stress level sₗ where sₗ<sₘ, leakage current Iₗ, and breakdown voltage Vₗ; wherein the reduced-stress bilayer is characterized by an overall stress level sₜₒₜ, overall leakage current Iₜₒₜ, and overall breakdown voltage Vₜₒₜ; and wherein sₜₒₜ<90%*sₘ; and wherein Iₜₒₜ<90%*(Iₘ*tₘ+Iₗ*tₗ)/(tₘ+tₗ), or Vₜₒₜ>110%*(Vₘ*tₘ+Vₗ*tₗ)/(tₘ+tₗ), or both.

System control instructions 858 may be configured in any suitable way. For example, various process tool component subroutines or control objects may be written to control operation of the process tool components necessary to carry out various process tool processes. System control instructions 858 may be coded in any suitable computer readable programming language. In some embodiments, system control instructions 858 are implemented in software, in other embodiments, the instructions may be implemented in hardware—for example, hard-coded as logic in an ASIC (application specific integrated circuit), or, in other embodiments, implemented as a combination of software and hardware.

In some embodiments, system control software 858 may include input/output control (IOC) sequencing instructions for controlling the various parameters described above. For example, each phase of a deposition process or processes may include one or more instructions for execution by system controller 850. The instructions for setting process conditions for a film deposition process phase, for example, may be included in a corresponding deposition recipe phase. In some embodiments, the recipe phases may be sequentially arranged, so that all instructions for a process phase are executed concurrently with that process phase.

Other computer-readable instructions and/or programs stored on mass storage device 854 and/or memory device 856 associated with system controller 850 may be employed in some embodiments. Examples of programs or sections of programs include a substrate positioning program, a process gas control program, a pressure control program, a heater control program, and a plasma control program.

A substrate positioning program may include instructions for process tool components that are used to load the substrate onto pedestal (see 508, FIG. 5) and to control the spacing between the substrate and other parts of process tool 500 of FIG. 5. The positioning program may include instructions for appropriately moving substrates in and out of the reaction chamber as necessary to deposit film on the substrates.

A process gas control program may include instructions for controlling gas composition and flow rates and optionally for flowing gas into the volumes surrounding one or more process stations prior to deposition in order to stabilize the pressure in these volumes. In some embodiments, the process gas control program may include instructions for introducing certain gases into the volume(s) surrounding the one or more process stations within a processing chamber during film deposition on substrates. The process gas control program may also include instructions to deliver these gases at the same rates, for the same durations, or at different rates and/or for different durations depending on the composition of the film being deposited. The process gas control program may also include instructions for atomizing/vaporizing a liquid reactant in the presence of helium or some other carrier gas in a heated injection module.

A pressure control program may include instructions for controlling the pressure in the process station by regulating, for example, a throttle valve in the exhaust system of the process station, a gas flow into the process station, etc. The pressure control program may include instructions for maintaining the same or different pressures during deposition of the various film types on the substrates.

A heater control program may include instructions for controlling the current to a heating unit that is used to heat the substrates. Alternatively or in addition, the heater control program may control delivery of a heat transfer gas (such as helium) to the substrate. The heater control program may include instructions for maintaining the same or different temperatures in the reaction chamber and/or volumes surrounding the process stations during deposition of the various film types on the substrates.

A plasma control program may include instructions for setting RF power levels, frequencies, and exposure times in one or more process stations in accordance with the embodiments herein. In some embodiments, the plasma control program may include instructions for using the same or different RF power levels and/or frequencies and/or exposure times during film deposition on the substrates.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas compositions and flow rates, temperatures (e.g., substrate holder and showerhead temperatures), pressures, plasma conditions (such as RF bias power levels and exposure times), etc. These parameters may be provided to the user in the form of a recipe, which may be entered utilizing the user interface.

Signals for monitoring the processes may be provided by analog and/or digital input connections of system controller 850 from various process tool sensors. The signals for controlling the processes may be output on the analog and/or digital output connections of process tool 800. Non-limiting examples of process tool sensors that may be monitored include mass flow controllers (MFCs), pressure sensors (such as manometers), temperature sensors such as thermocouples, etc. Appropriately programmed feedback and control algorithms may be used with data from these sensors to maintain process conditions.

System controller 850 may provide machine-readable instructions for implementing the above-described deposition processes. The instructions may control a variety of process parameters, such as DC power level, RF bias power level, pressure, temperature, etc. The instructions may control the parameters to perform film deposition operations as described herein.

Thus, the system controller will typically include one or more memory devices and one or more processors configured to execute machine-readable instructions so that the apparatus will perform operations in accordance with the processes disclosed herein. Machine-readable, non-transitory media containing instructions for controlling operations in accordance with the substrate processing operations disclosed herein may be coupled to the system controller.

The various apparatuses and methods described above may be used in conjunction with lithographic patterning tools and/or processes, for example, for the fabrication or manufacture of semiconductor devices, displays, LEDs, photovoltaic panels and the like. Typically, though not necessarily, such tools will be used or processes conducted together and/or contemporaneously in a common fabrication facility.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Lithographic Patterning

Lithographic patterning of a film typically includes some or all of the following operations, each operation enabled with a number of possible tools: (1) application of photoresist on a substrate, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or substrate by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

### Other Embodiments

Although the foregoing disclosed techniques, operations, processes, methods, systems, apparatuses, tools, films, chemistries, and compositions have been described in detail within the context of specific embodiments for the purpose of promoting clarity and understanding, it will be apparent to one of ordinary skill in the art that there are many alternative ways of implementing foregoing embodiments which are within the spirit and scope of this disclosure. Accordingly, the embodiments described herein are to be viewed as illustrative of the disclosed inventive concepts rather than restrictively, and are not to be used as an impermissible basis for unduly limiting the scope of any claims eventually directed to the subject matter of this disclosure.

1. A method of forming a reduced-stress dielectric film on a semiconductor substrate, the method comprising:
depositing a first reduced-stress bilayer of the dielectric film by:
(i) depositing a main portion having a thickness tₘ and stress level sₘ; and
(ii) depositing a low stress portion having a thickness tₗ and stress level sₗ where sₗ<sₘ;
wherein the first reduced-stress bilayer deposited according to (i)-(ii) is characterized by an overall stress level sₜₒₜ, and wherein
sₜₒₜ<90%*(sₘ*tₘ+sₗ*tₗ)/(tₘ+tₗ).

2. The method of claim 1, wherein sₜₒₜ and sₗ corresponding to the first reduced-stress bilayer are such that sₜₒₜ<ₗ.

3. The method of claim 1, further comprising:
depositing a second reduced-stress bilayer of dielectric film according to (i)-(ii);
wherein the second reduced-stress bilayer deposited according to (i)-(ii) is also characterized by an overall stress level sₜₒₜ wherein
sₜₒₜ<90%*(sₘ*tₘ+sₗ*tₗ)/(tₘ+tₗ).

4. The method of claim 3, wherein sₜₒₜ and sₗ corresponding to the first reduced-stress bilayer are such that sₜₒₜ<sₗ, and likewise for the second reduced-stress bilayer.

5. The method of claim 1, wherein sₜₒₜ, sₘ, and sₗ corresponding to the first reduced-stress bilayer are such that sₘ>200 MPa compressive, sₗ<200 MPa compressive, and sₜₒₜ<200 MPa compressive.

6. The method of claim 1, wherein sₜₒₜ, sₘ, and sₗ corresponding to the first reduced-stress bilayer are such that sₘ>200 MPa tensile, sₗ<200 MPa tensile, and sₜₒₜ<200 MPa tensile.

7. The method of claim 1, wherein the main and low stress portions of the first reduced-stress bilayer have substantially the same chemical composition within a margin of 5 mole percent per unit volume for each individual elemental component.

8. The method of claim 7, wherein the dielectric film comprises oxides, nitrides, and/or carbides of silicon.

9. The method of claim 1, wherein depositing the main portion of the first reduced-stress bilayer in (i) and depositing the low stress portion in (ii) each comprise:
(a) adsorbing a film precursor onto the substrate in a processing chamber such that the film precursor forms an adsorption-limited layer of film precursor on the substrate;
(b) removing at least some unadsorbed film precursor from a volume within the processing chamber surrounding the adsorbed film precursor; and
(c) after removing unadsorbed film precursor in (b), reacting the adsorbed film precursor by exposing it to a plasma to form a dielectric film layer on the substrate.

10. The method of claim 1, further comprising depositing an additional single layer of film by either operation (i) or operation (ii).

11. The method of claim 1, wherein depositing the main portion of the first reduced-stress bilayer in (i) and depositing the low stress portion in (ii) each comprise a PVD or CVD process.

12. A method of forming a reduced-stress dielectric film on a semiconductor substrate, the method comprising:
depositing a first reduced-stress bilayer of dielectric film by:
(i) depositing a main portion having a thickness tₘ and stress level sₘ; and
(ii) depositing a low stress portion having a thickness tₗ and stress level sₗ where sₗ<sₘ;
wherein the first reduced-stress bilayer deposited according to (i)-(ii) is characterized by an overall stress level sₜₒₜ<90%*sₘ, and wherein the main and low stress portions of the first reduced-stress bilayer have substantially the same chemical composition within a margin of 5.0 mole percent per unit volume for each individual elemental component.

13. The method of claim 12, wherein the main portion of the first reduced-stress bilayer is deposited in (i) before the low stress portion is deposited in (ii).

14. The method of claim 12, wherein the main portion of the first reduced-stress bilayer is deposited in (i) after the low stress portion is deposited in (ii).

15. The method of claim 12, further comprising depositing an additional single layer of film by either operation (i) or (ii).

16. The method of claim 12, wherein the first reduced-stress bilayer has a thickness ratio of tₗ/tₘ>33%.

17. The method of claim 12, wherein depositing the main portion of the first reduced-stress bilayer in (i) and the low stress portion in (ii) each comprise:
(a) adsorbing a film precursor onto the substrate in a processing chamber such that the film precursor forms an adsorption-limited layer of film precursor on the substrate;
(b) removing at least some unadsorbed film precursor from a volume within the processing chamber surrounding the adsorbed film precursor; and
(c) after removing unadsorbed film precursor in (b), reacting the adsorbed film precursor by exposing it to a plasma to form a dielectric film layer on the substrate.

18. A method of forming a reduced-stress dielectric film on a semiconductor substrate, the method comprising:
depositing a first reduced-stress bilayer of dielectric film by:
(i) depositing a main portion having a thickness tₘ, stress level sₘ, leakage current Iₘ, and breakdown voltage Vₘ; and
(ii) depositing a low stress portion having a thickness tₗ, stress level sₗ where sₗ<sₘ, leakage current Iₗ, and breakdown voltage Vₗ;
wherein the first reduced-stress bilayer deposited according to (i)-(ii) is characterized by an overall stress level sₜₒₜ, overall leakage current Iₜₒₜ, and overall breakdown voltage Vₜₒₜ; and
wherein sₜₒₜ<90%*sₘ; and
wherein
Iₜₒₜ<90%*(Iₘ*tₘ+Iₗ*tₗ)/(tₘ+tₗ), or
Vₜₒₜ>110%*(Vₘ*tₘ+Vₗ*tₗ)/(tₘ+tₗ),
or both.

19. The method of claim 18, wherein sₜₒₜ and sₘ of the first bilayer are such that sₜₒₜ<80%*sₘ.

20. The method of claim 18, wherein
Iₜₒₜ<80%*(Iₘ*tₘ+Iₗ*tₗ)/(tₘ+tₗ), or
Vₜₒₜ>120%*(Vₘ*tₘ+Vₗ*tₗ)/(tₘ+tₗ),
or both.

21. The method of claim 18, wherein depositing the main portion of the first reduced-stress bilayer in (i) and the low stress portion in (ii) each comprise:
(a) adsorbing a film precursor onto the substrate in a processing chamber such that the film precursor forms an adsorption-limited layer of film precursor on the substrate;
(b) removing at least some unadsorbed film precursor from a volume within the processing chamber surrounding the adsorbed film precursor; and
(c) after removing unadsorbed film precursor in (b), reacting the adsorbed film precursor by exposing it to a plasma to form a dielectric film layer on the substrate.

22. The method of claim 21, wherein the dielectric film comprises oxides, nitrides, and/or carbides of silicon.
